(19) United States
(12) Patent Application Publication
(10) Pub. No.: US 2026/0123141 A1
(43) Pub. Date: Apr. 30, 2026

(54) DISPLAY PANEL AND ELECTRONIC DEVICE INCLUDING THE DISPLAY PANEL

(71) Applicant: Samsung Display Co., LTD., Yongin-si (KR)

(72) Inventors: Sujin Jeong, Yongin-si (KR); Jinwoo Choi, Yongin-si (KR); Hyelan Kim, Yongin-si (KR); Kangyoung Lee, Yongin-si (KR)

(21) Appl. No.: 19/343,271

(22) Filed: Sep. 29, 2025

(30) Foreign Application Priority Data
Oct. 29, 2024 (KR) 10-2024-0149990

(51) Int. Cl. H10H 29/49

(52) U.S. Cl. CPC H10H 29/49

(57) ABSTRACT

Provided is a display panel including a substrate including a plurality of island portions and a plurality of bridge portions connecting adjacent island portions among the plurality of island portions to each other, a display layer arranged on the substrate and including a plurality of pixels and a plurality of wirings. The plurality of pixels are arranged in the plurality of island portions, and the plurality of wirings are arranged in the plurality of bridge portions. The display panel includes a first protective layer covering a side surface of the substrate and a side surface of the display layer. The first protective layer is arranged such that the first protective layer is spaced apart from the plurality of pixels in a plan view.

This application claims priority to Korean Patent Application No. 10-2024-0149990, filed on Oct. 29, 2024, and all the benefits accruing therefrom under 35 U.S.C. § 119, the content of which in its entirety is herein incorporated by reference.

### BACKGROUND

### 1. Field

One or more embodiments relate to a display panel and an electronic device including the display panel, and more particularly, to a flexible display panel and an electronic device including the display panel.

### 2. Description of the Related Art

With the development of display panels that visually display electrical signals, various electronic devices having excellent characteristics, such as thinness, light weight, and low power consumption, have been introduced. For example, electronic devices may include flexible display panels that are foldable or rollable. Recently, research and development have been actively conducted on various electronic devices including stretchable display panels that may be changed into various shapes.

### SUMMARY

One or more embodiments include a display panel, for example, a flexible display panel, and an electronic device including the display panel.

Additional aspects will be set forth in part in the description which follows and, in part, will be apparent from the description, or may be learned by practice of the presented embodiments of the disclosure.

According to one or more embodiments, a display panel includes a substrate including a plurality of island portions and a plurality of bridge portions connecting adjacent island portions among the plurality of island portions to each other, a display layer arranged on the substrate and including a plurality of pixels and a plurality of wirings, wherein the plurality of pixels are arranged in the plurality of island portions, and the plurality of wirings are arranged in the plurality of bridge portions, and a first protective layer covering a side surface of the substrate and a side surface of the display layer, wherein the first protective layer is arranged such that the first protective layer is spaced apart from the plurality of pixels in a plan view.

The substrate may further include at least one base layer including an organic insulating material, and at least one barrier layer arranged on the at least one base layer and including an inorganic insulating material, wherein the at least one barrier layer may be spaced apart from the plurality of bridge portions in the plan view.

The display layer may further include a pixel circuit arranged in each of the plurality of island portions, a first organic insulating layer arranged on the pixel circuit, a first electrode pad and a second electrode pad that are arranged on the first organic insulating layer, and a light-emitting diode arranged on the first electrode pad and the second electrode pad.

The display layer may further include at least one inorganic insulating layer, and the at least one inorganic insulating layer may be spaced apart from the plurality of bridge portions in the plan view.

The display panel may further include an encapsulation layer arranged on the light-emitting diode, wherein the first protective layer may cover a side surface of the encapsulation layer.

The first protective layer may expose an upper surface of the encapsulation layer.

Each of the plurality of bridge portions may have a serpentine shape.

Each of the plurality of bridge portions may include two round portions each having an inner edge and an outer edge, and a connection portion connecting the two round portions to each other.

Each of the plurality of bridge portions may have a wiring area in which the plurality of wirings are arranged, wherein the wiring area may be spaced apart from the outer edge by a first distance, and may be spaced apart from the inner edge by a second distance that is greater than the first distance.

The display panel may further include a second protective layer arranged between the inner edges and the first protective layer.

A modulus of the second protective layer may be higher than a modulus of the first protective layer.

Each of the plurality of bridge portions may include two corner portions each having a first portion and a second portion that are connected to each other, the first portion extending in a first direction, and the second portion extending in a second direction crossing the first direction, and a connection portion connecting the two corner portions to each other.

Each of the two corner portions may have an inner edge and an outer edge, and the display panel may further include a second protective layer arranged between the inner edges and the first protective layer.

A modulus of the second protective layer may be higher than a modulus of the first protective layer.

The first protective layer may include parylene, silicon oxide, or silicon nitride.

According to one or more embodiments, a display panel includes a substrate including a plurality of island portions and a plurality of bridge portions connecting adjacent island portions among the plurality of island portions to each other, a pixel circuit arranged in each of the plurality of island portions, a first organic insulating layer arranged on the pixel circuit, a first electrode pad and a second electrode pad that are arranged on the first organic insulating layer, a light-emitting diode arranged on the first electrode pad and the second electrode pad, a first protective layer extending from an upper surface of the first organic insulating layer to a side surface of the substrate and having openings respectively corresponding to the first electrode pad and the second electrode pad, and a second protective layer arranged between the first protective layer and side surfaces of the plurality of bridge portions.

The substrate may further include at least one base layer including an organic insulating material, and at least one barrier layer arranged on the at least one base layer and including an inorganic insulating material, wherein the at least one barrier layer may be spaced apart from the plurality of bridge portions in a plan view.

Each of the plurality of bridge portions may include two round portions each having an inner edge and an outer edge, and a connection portion connecting the two round portions to each other, wherein the second protective layer may be arranged along the inner edges.

A modulus of the second protective layer may be higher than a modulus of the first protective layer.

According to one or more embodiments, an electronic device includes a display panel capable of being stretched, wherein the display panel includes a substrate including a plurality of island portions and a plurality of bridge portions connecting adjacent island portions among the plurality of island portions to each other, a display layer arranged on the substrate and including a plurality of pixels and a plurality of wirings, wherein the plurality of pixels are arranged in the plurality of island portions, and the plurality of wirings are arranged in the plurality of bridge portions, and a first protective layer covering a side surface of the substrate and a side surface of the display layer, wherein the first protective layer is arranged such that the first protective layer is spaced apart from the plurality of pixels in a plan view.

Other aspects, features, and advantages than those described herein will be apparent from the following drawings, claims, and detailed description.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display panel according to an embodiment;

FIGS. 2A and 2B are each a perspective view of a state in which the display panel of FIG. 1 is stretched in a first direction;

FIG. 2C is a perspective view of a state in which the display panel of FIG. 1 is stretched in a second direction;

FIG. 2D is a perspective view of a state in which the display panel of FIG. 1 is stretched in the first and second directions;

FIG. 2E is a perspective view of a state in which the display panel of FIG. 1 is stretched in a third direction;

FIGS. 3A to 3C are each an equivalent circuit diagram of a pixel included in a display panel, according to an embodiment;

FIGS. 4A to 4C are each a schematic plan view of a display area of a display panel according to an embodiment;

FIG. 5 is a schematic cross-sectional view of the display panel, taken along a line I-I′ of FIG. 4A;

FIGS. 6A to 6E are each a schematic cross-sectional view of a light-emitting diode of a display panel according to an embodiment;

FIG. 7 is a schematic cross-sectional view of a portion of a display area of a display panel according to an embodiment;

FIG. 8A is a schematic plan view of a bridge portion of a display panel according to an embodiment;

FIG. 8B is a schematic cross-sectional view of the bridge portion, taken along a line II-II′ of FIG. 8A;

FIG. 9A is a schematic plan view of a bridge portion of a display panel according to an embodiment;

FIG. 9B is a schematic cross-sectional view of the bridge portion, taken along a line III-III′ of FIG. 9A;

FIG. 10 is a schematic plan view of a display area of a display panel according to an embodiment;

FIG. 11A is a schematic cross-sectional view of a portion of a display area of a display panel according to an embodiment;

FIG. 11B is a schematic cross-sectional view of a portion of a bridge portion of the display panel of FIG. 11A;

FIG. 12 is a block diagram of an electronic device including a display panel, according to an embodiment; and

FIGS. 13A to 13G are each a schematic perspective view of an electronic device including a display panel, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the example embodiments are described herein, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in detail in the written description. Effects and features of the disclosure and methods of achieving the same will be apparent by referring to the drawings and embodiments described in detail below. However, the disclosure is not limited to the following embodiments and may be embodied in various forms.

Hereinafter, embodiments of the disclosure will be described in detail with reference to the accompanying drawings, and in the description with reference to the drawings, the same or corresponding components are indicated by the same reference numerals and redundant descriptions thereof are omitted.

In the present specification, it will be understood that although the terms “first,” “second,” and the like may be used to describe various components, these components should not be limited by these terms. These terms are used to distinguish one component from another.

In the present specification, the expression of singularity includes the expression of plurality unless clearly specified otherwise in context.

In the present specification, it will be understood that the terms “comprise,” “comprising,” “include,” and/or “including” specify the presence of stated features or components, but do not preclude the presence or addition of one or more other features or components.

In the present specification, it will be understood that when a layer, area, or component is referred to as being “on” or “above” another layer, area, or component, it can be directly or indirectly on or above the other layer, area, or component. That is, for example, intervening layers, areas, or components may be present.

In the present specification, it will be understood that when a layer, area, or component is referred to as being “connected” to another layer, area, or component, it can be directly and/or indirectly connected to the other layer, area, or component. That is, for example, intervening layers, areas, or components may be present. For example, it will be understood that when a layer, area, or component is referred to as being “electrically connected” to another layer, area, or component, it can be directly and/or indirectly electrically connected to the other layer, area, or component. That is, for example, intervening layers, areas, or components may be present.

In the present specification, the expression “A and/or B” represents A, B, or A and B. In some aspects, the expression “at least one of A and B”represents A, B, or A and B.

In the present specification, an x-direction, a y-direction, and a z-direction are not limited to directions along three axes of the rectangular coordinate system, and may be interpreted in a broader sense. For example, the x-direction, the y-direction, and the z-direction may be perpendicular to one another, or may represent different directions that are not perpendicular to one another.

In the present specification, the expression “in a plan view” means viewing a target portion from the top (e.g., in a direction perpendicular to a top surface of a substrate), and the expression “in a cross-sectional view” means viewing a cross-section formed by vertically cutting a target portion from the side.

In the present specification, when a first component is referred to as “overlapping” a second component, the first component is located above or below the second component such that at least portions thereof overlap in a plan view.

In the present specification, when a certain embodiment may be implemented differently, a specific process order may be performed differently from the described order. For example, two processes described in succession may be performed substantially simultaneously, or may be performed in an order opposite to the order described.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel. The term “substantially simultaneously” means approximately or actually simultaneously.

Sizes of components in the drawings may be exaggerated for convenience of description. For example, because sizes and thicknesses of components in the drawings are arbitrarily illustrated for convenience of description, the following embodiments are not limited thereto.

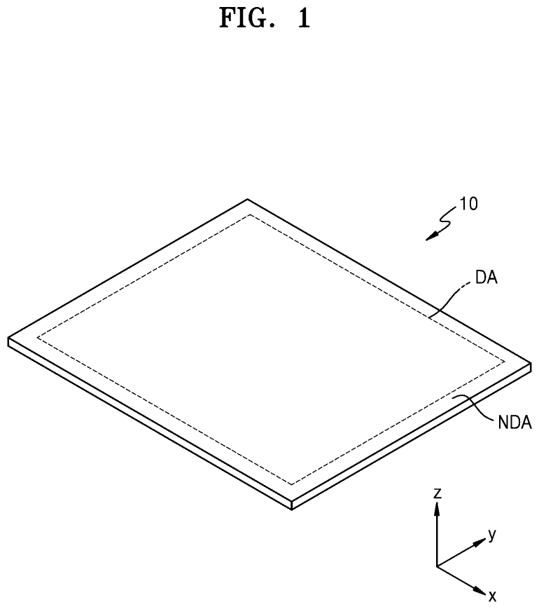

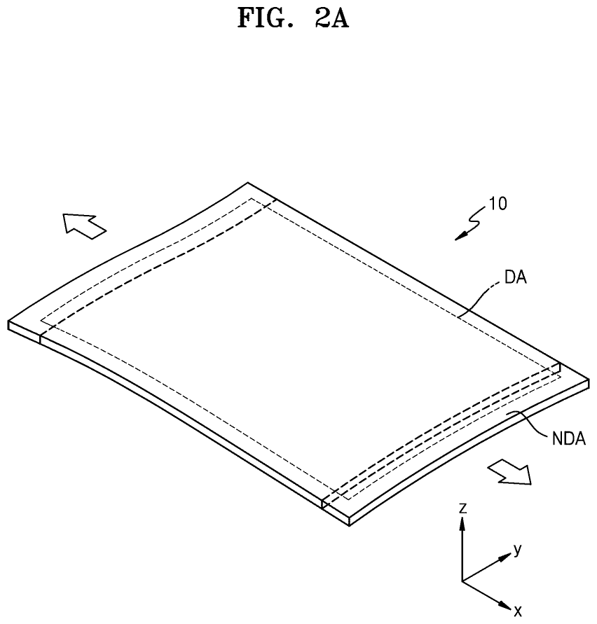

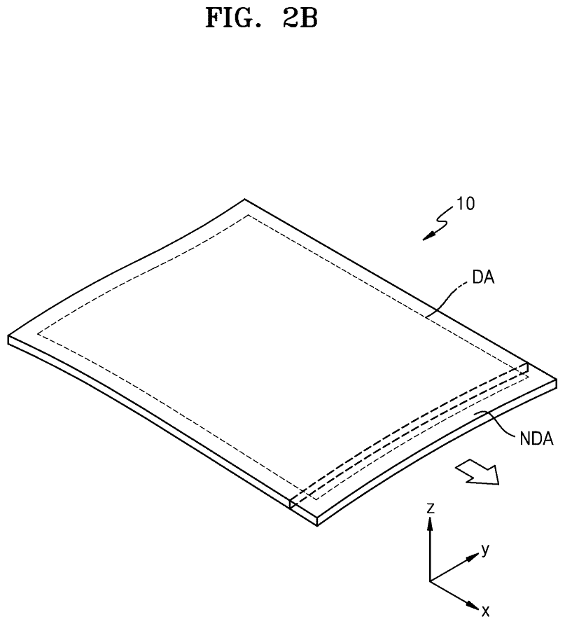

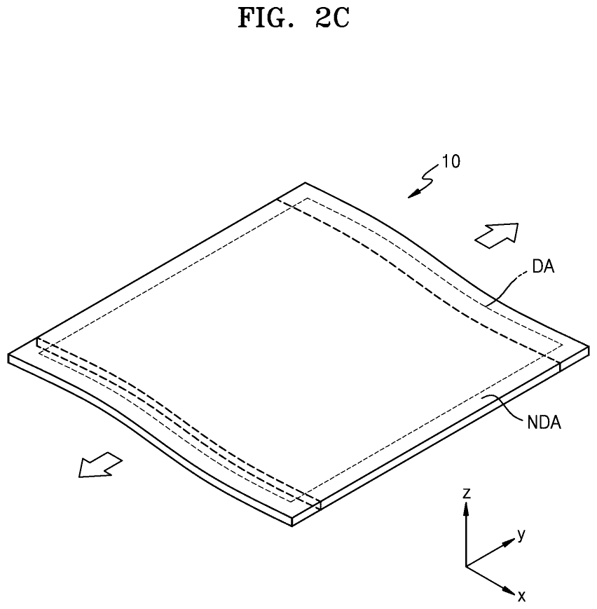

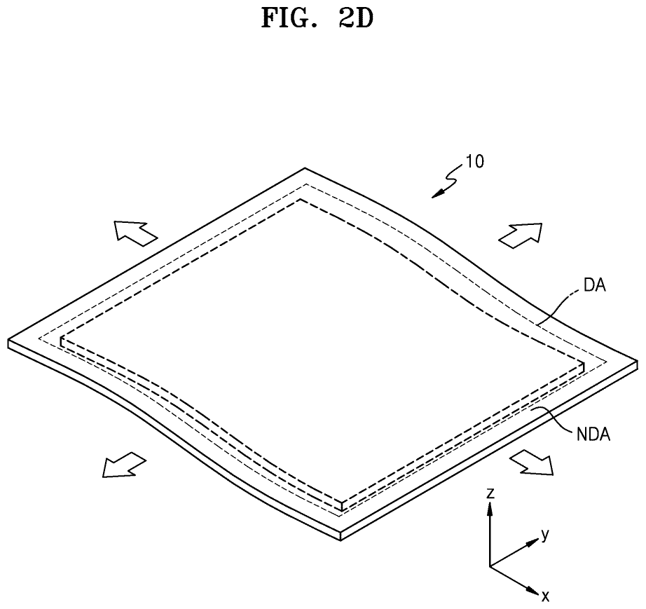

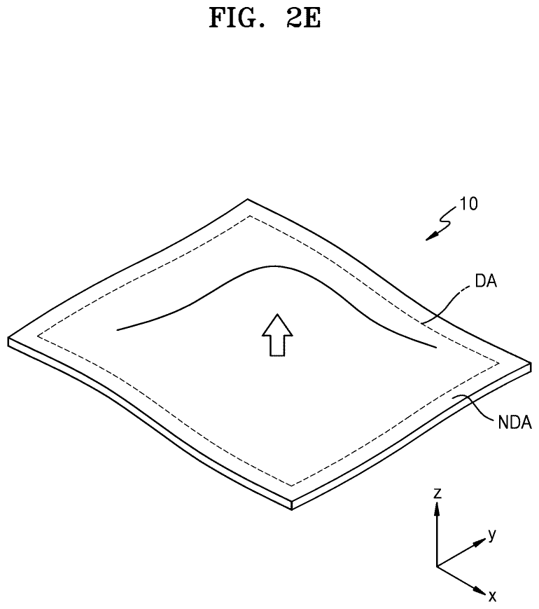

FIG. 1 is a schematic perspective view of a display panel 10 according to an embodiment. FIGS. 2A and 2B are each a perspective view of a state in which the display panel 10 of FIG. 1 is stretched in a first direction. FIG. 2C is a perspective view of a state in which the display panel 10 of FIG. 1 is stretched in a second direction. FIG. 2D is a perspective view of a state in which the display panel 10 of FIG. 1 is stretched in the first and second directions. FIG. 2E is a perspective view of a state in which the display panel 10 of FIG. 1 is stretched in a third direction.

Referring to FIG. 1, the display panel 10 may include a display area DA and a non-display area NDA. The display area DA may include a plurality of pixels. The display panel 10 may provide a certain image by using light emitted from the plurality of pixels. The non-display area NDA may be arranged outside the display area DA. The non-display area NDA may entirely surround the display area DA.

The display panel 10 may be stretched or shrunk in various directions. The display panel 10 may be stretched in a first direction (e.g., an x-direction and/or a −x-direction) due to an external force applied by an external object or a user. In an embodiment, as illustrated in FIGS. 2A and 2B, the display area DA and/or the non-display area NDA of the display panel 10 may be stretched in the first direction (e.g., the x-direction and/or the −x-direction). For example, the display panel 10 may be stretched in the x-direction and the x-direction, as illustrated in FIG. 2A, or may be stretched in the x-direction while one side of the display panel 10 is fixed, as illustrated in FIG. 2B.

The display panel 10 may be stretched in a second direction (e.g., a y-direction and/or a −y-direction) due to an external force applied by an external object or a user. In an embodiment, as illustrated in FIG. 2C, the display area DA and/or the non-display area NDA of the display panel 10 may be stretched in the y-direction and the −y-direction. In another embodiment, the display panel 10 may be stretched in the y-direction or the −y-direction while one side of the display panel 10 is fixed.

The display panel 10 may be stretched in a plurality of directions, for example, in the first direction (e.g., the x-direction and/or the −x-direction) and the second direction (e.g., the y-direction and/or the −y-direction), due to an external force applied by an external object or a part of the human body. As illustrated in FIG. 2D, the display area DA and/or the non-display area NDA of the display panel 10 may be stretched in the ±x-direction and the ±y-direction.

The display panel 10 may be stretched in a third direction (e.g., a z-direction or a −z-direction) due to an external force applied by an external object or a part of the human body. In an embodiment, FIG. 2E illustrates that a portion of the display panel 10, for example, a portion of the display area DA, protrudes in the z-direction. In another embodiment, a portion of the display panel 10, for example, a portion of the display area DA, may protrude in the z-direction (or be recessed in the −z-direction).

FIGS. 2A to 2E show that the display panel 10 is stretched in the first direction, the second direction, and/or the third direction, but the disclosure is not limited thereto. In another embodiment, the display panel 10 may be variously deformed into an irregular shape, for example, may be bent or twisted along two or more axes.

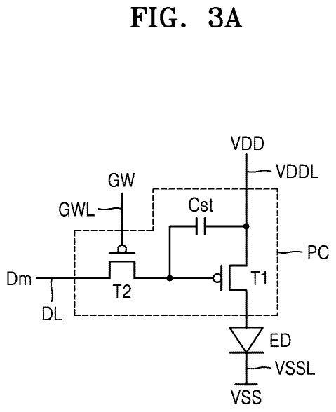

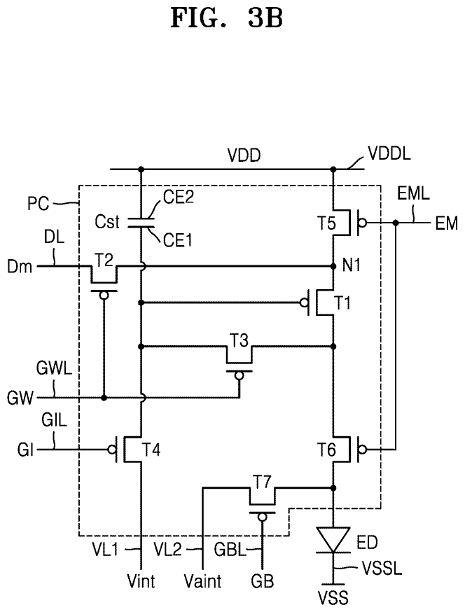

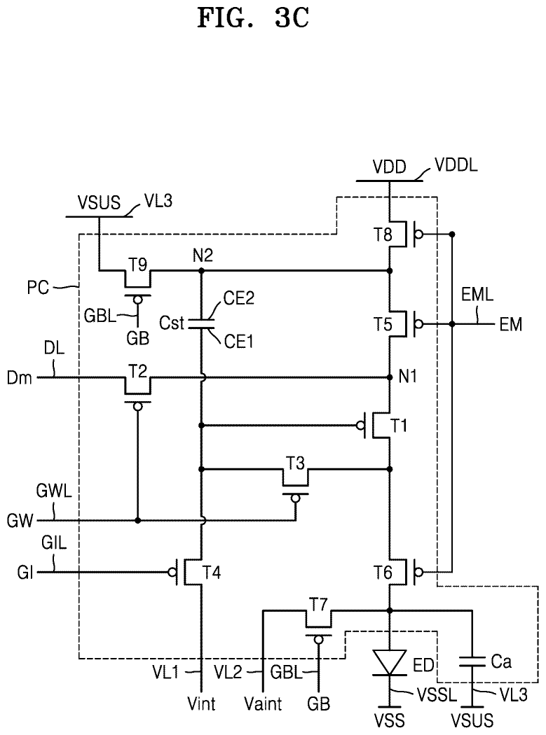

FIGS. 3A to 3C are each an equivalent circuit diagram of a pixel included in a display panel, according to an embodiment.

Referring to FIG. 3A, a pixel may include a light-emitting diode ED and a pixel circuit PC that controls the luminance of the light-emitting diode ED. The light-emitting diode ED may be electrically connected to the pixel circuit PC, and the pixel circuit PC may include a first transistor T1, a second transistor T2, and a storage capacitor Cst. The pixel circuit PC may be electrically connected to a signal line and a voltage line. The signal line may include a scan signal line GWL and a data line DL, and the voltage line may include a first voltage line VDDL and a second voltage line VSSL.

The second transistor T2 may be electrically connected to the scan signal line GWL and the data line DL. The scan signal line GWL may provide a scan signal GW to a gate electrode of the second transistor T2. The second transistor T2 may be configured to transmit, to the first transistor T1, a data signal Dm input from the data line DL, according to the scan signal GW input from the scan signal line GWL.

The storage capacitor Cst may be electrically connected to the second transistor T2 and the first voltage line VDDL, and may store a voltage corresponding to a difference between a voltage received from the second transistor T2 and a first power voltage VDD supplied by the first voltage line VDDL.

The first transistor T1 may be a driving transistor, and may control a driving current flowing through the light-emitting diode ED. The first transistor T1 may be connected to the first voltage line VDDL and the storage capacitor Cst. The first transistor T1 may control a driving current flowing from the first voltage line VDDL to the light-emitting diode ED, in response to a voltage value stored in the storage capacitor Cst. The light-emitting diode ED may emit light having a certain luminance according to the driving current. A first electrode of the light-emitting diode ED may be electrically connected to the first transistor T1, and a second electrode of the light-emitting diode ED may be electrically connected to the second voltage line VSSL configured to supply a second power voltage VSS.

Although FIG. 3A illustrates that the pixel circuit PC includes two transistors and one storage capacitor, in another embodiment, the pixel circuit PC may include three or more transistors.

Referring to FIG. 3B, the pixel circuit PC may include a first transistor T1, a second transistor T2, a third transistor T3, a fourth transistor T4, a fifth transistor T5, a sixth transistor T6, a seventh transistor T7, and a storage capacitor Cst.

The pixel circuit PC may be electrically connected to signal lines and voltage lines. The signal lines may include gate lines, such as, for example, a scan signal line GWL, a bypass control line GBL, an initialization control line GIL, and an emission control line EML, and a data line DL. The voltage lines may include first and second initialization voltage lines VL1 and VL2, a first voltage line VDDL, and a second voltage line VSSL.

The first voltage line VDDL may be configured to transmit a first power voltage VDD to the first transistor T1. The first initialization voltage line VL1 may be configured to transmit a first initialization voltage Vint for initializing the first transistor T1 to the pixel circuit PC. The second initialization voltage line VL2 may be configured to transmit a second initialization voltage Vaint for initializing the first electrode of the light-emitting diode ED to the pixel circuit PC.

The first transistor T1 may be electrically connected to the first voltage line VDDL through the fifth transistor T5, and may be electrically connected to the light-emitting diode ED through the sixth transistor T6. The first transistor T1 may serve as a driving transistor, and may be configured to receive a data signal Dm according to a switching operation of the second transistor T2 and supply a driving current to the light-emitting diode ED.

The second transistor T2 may be a data writing transistor, and may be electrically connected to the scan signal line GWL and the data line DL. The second transistor T2 may be electrically connected to the first voltage line VDDL through the fifth transistor T5. The second transistor T2 may be turned on according to a scan signal GW received through the scan signal line GWL, and may be configured to perform a switching operation of transmitting, to a first node N1, the data signal Dm transmitted through the data line DL.

The third transistor T3 may be electrically connected to the scan signal line GWL, and may be electrically connected to the light-emitting diode ED through the sixth transistor T6. The third transistor T3 may be turned on according to the scan signal GW received through the scan signal line GWL to diode-connect the first transistor T1.

The fourth transistor T4 may be a first initialization transistor, and may be electrically connected to the initialization control line GIL and the first initialization voltage line VL1. The fourth transistor T4 may be turned on according to an initialization control signal GI received through the initialization control line GIL, and may be configured to transmit, to a gate electrode of the first transistor T1, the first initialization voltage Vint from the first initialization voltage line VL1 to initialize a voltage of the gate electrode of the first transistor T1. The initialization control signal GI may correspond to a scan signal of another pixel circuit arranged in a previous row of the pixel circuit PC.

The fifth transistor T5 may be an operation control transistor, and the sixth transistor T6 may be an emission control transistor. The fifth transistor T5 and the sixth transistor T6 may be electrically connected to the emission control line EML, and may be simultaneously turned on according to an emission control signal EM received through the emission control line EML to form a current path, and thus, a driving current may flow from the first voltage line VDDL to the light-emitting diode ED. The first electrode of the light-emitting diode ED may be electrically connected to the first transistor T1 through the sixth transistor T6, and the second electrode of the light-emitting diode ED may be electrically connected to the second voltage line VSSL configured to supply a second power voltage VSS.

The seventh transistor T7 may be a second initialization transistor, and may be electrically connected to the bypass control line GBL, the second initialization voltage line VL2, and the sixth transistor T6. The seventh transistor T7 may be turned on according to a bypass control signal GB received through the bypass control line GBL, and may be configured to transmit, to the first electrode of the light-emitting diode ED, the second initialization voltage Vaint from the second initialization voltage line VL2 to initialize the first electrode of the light-emitting diode ED.

The storage capacitor Cst may include a first electrode CE1 and a second electrode CE2. The first electrode CE1 may be electrically connected to the gate electrode of the first transistor T1, and the second electrode CE2 may be electrically connected to the first voltage line VDDL. The storage capacitor Cst may store and maintain a voltage corresponding to a difference between voltages of the first voltage line VDDL and the gate electrode of the first transistor T1, thereby maintaining a voltage applied to the gate electrode of the first transistor T1.

Referring to FIG. 3C, the pixel circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel circuit PC may be electrically connected to signal lines and voltage lines. The signal lines may include gate lines, such as, for example, a scan signal line GWL, a bypass control line GBL, an initialization control line GIL, and an emission control line EML, and a data line DL. The voltage lines may include first and second initialization voltage lines VL1 and VL2, a sustain voltage line VL3, a first voltage line VDDL, and a second voltage line VSSL.

The first voltage line VDDL may be configured to transmit a first power voltage VDD to the first transistor T1. The first initialization voltage line VL1 may be configured to transmit a first initialization voltage Vint for initializing the first transistor T1 to the pixel circuit PC. The second initialization voltage line VL2 may be configured to transmit a second initialization voltage Vaint for initializing the first electrode of the light-emitting diode ED to the pixel circuit PC. The sustain voltage line VL3 may be configured to provide a sustain voltage VSUS to a second node N2, for example, a second electrode CE2 of the storage capacitor Cst, in an initialization section and a data writing section.

The first transistor T1 may be electrically connected to the first voltage line VDDL through the fifth transistor T5 and the eighth transistor T8, and may be electrically connected to the light-emitting diode ED through the sixth transistor T6. The first transistor T1 may serve as a driving transistor, and may be configured to receive a data signal Dm according to a switching operation of the second transistor T2 and supply a driving current to the light-emitting diode ED.

The second transistor T2 may be electrically connected to the scan signal line GWL and the data line DL, and may be electrically connected to the first voltage line VDDL through the fifth transistor T5 and the eighth transistor T8. The second transistor T2 may be turned on according to a scan signal GW received through the scan signal line GWL, and may be configured to perform a switching operation of transmitting, to a first node N1, the data signal Dm transmitted through the data line DL.

The third transistor T3 may be electrically connected to the scan signal line GWL, and may be electrically connected to the light-emitting diode ED through the sixth transistor T6. The third transistor T3 may be turned on according to the scan signal GW received through the scan signal line GWL to diode-connect the first transistor T1, thereby compensating for a threshold voltage of the first transistor T1.

The fourth transistor T4 may be electrically connected to the initialization control line GIL and the first initialization voltage line VL1, may be turned on according to an initialization control signal GI received through the initialization control line GIL, and may be configured to transmit, to a gate electrode of the first transistor T1, the first initialization voltage Vint from the first initialization voltage line VL1 to initialize a voltage of the gate electrode of the first transistor T1. The initialization control signal GI may correspond to a scan signal of another pixel circuit arranged in a previous row of the pixel circuit PC.

The fifth transistor T5, the sixth transistor T6, and the eighth transistor T8 may be electrically connected to the emission control line EML, and may be simultaneously turned on according to an emission control signal EM received through the emission control line EML to form a current path, and thus, a driving current may flow from the first voltage line VDDL to the light-emitting diode ED. The first electrode of the light-emitting diode ED may be electrically connected to the first transistor T1 through the sixth transistor T6, and the second electrode of the light-emitting diode ED may be electrically connected to the second voltage line VSSL configured to supply a second power voltage VSS.

The seventh transistor T7 may be a second initialization transistor, and may be electrically connected to the bypass control line GBL, the second initialization voltage line VL2, and the sixth transistor T6. The seventh transistor T7 may be turned on according to a bypass control signal GB received through the bypass control line GBL, and may be configured to transmit, to the first electrode of the light-emitting diode ED, the second initialization voltage Vaint from the second initialization voltage line VL2 to initialize the first electrode of the light-emitting diode ED.

The ninth transistor T9 may be electrically connected to the bypass control line GBL, the second electrode CE2 of the storage capacitor Cst, and the sustain voltage line VL3. The ninth transistor T9 may be turned on according to the bypass control signal GB received through the bypass control line GBL, and may be configured to transmit the sustain voltage VSUS to the second node N2, for example, the second electrode CE2 of the storage capacitor Cst, in an initialization section and a data writing section.

The eighth transistor T8 and the ninth transistor T9 may each be electrically connected to the second node N2, for example, the second electrode CE2 of the storage capacitor Cst. In some embodiments, in an initialization section and a data writing section, the eighth transistor T8 may be turned off and the ninth transistor T9 may be turned on, and in an emission section, the eighth transistor T8 may be turned on and the ninth transistor T9 may be turned off.

The storage capacitor Cst may include a first electrode CE1 and a second electrode CE2. The first electrode CE1 may be electrically connected to the gate electrode of the first transistor T1, and the second electrode CE2 may be electrically connected to the eighth transistor T8 and the ninth transistor T9.

The auxiliary capacitor Ca may be electrically connected to the sixth transistor T6, the sustain voltage line VL3, and the first electrode of the light-emitting diode ED. The auxiliary capacitor Ca may store and maintain a voltage corresponding to a difference between voltages of the first electrode of the light-emitting diode ED and the sustain voltage line VL3 while the seventh transistor T7 and the ninth transistor T9 are turned on, and thus, an increase in black luminance may be prevented when the sixth transistor T6 is turned off.

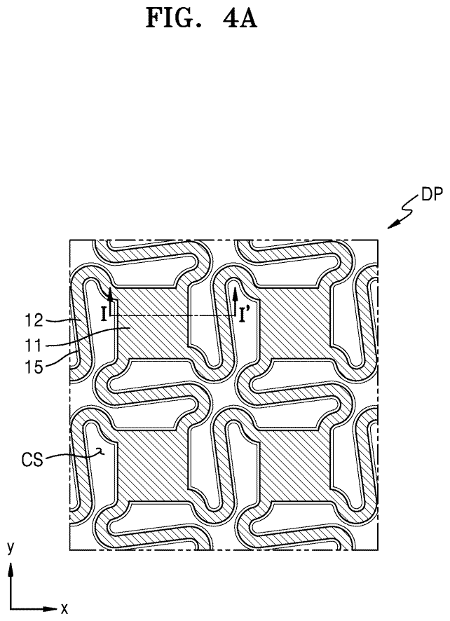

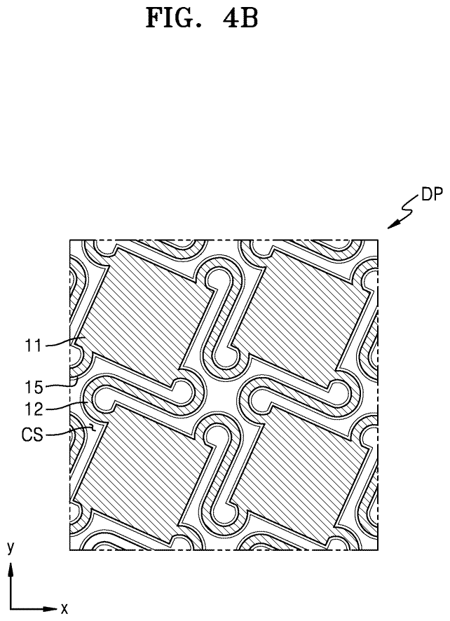

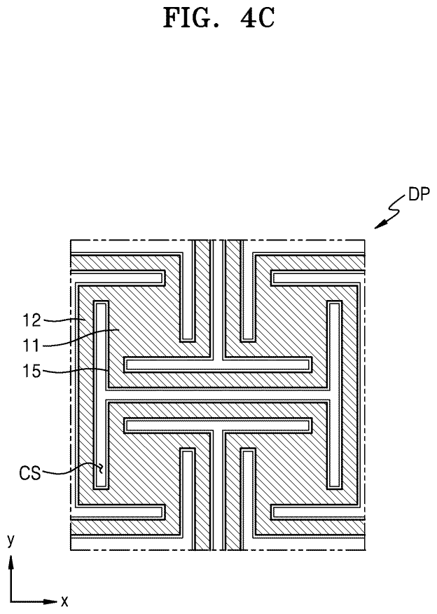

FIGS. 4A to 4C are each a schematic plan view of a display area of a display panel according to an embodiment.

Referring to FIG. 4A, the display panel 10 may include a plurality of first island portions 11 spaced apart from each other in the first direction (e.g., the x-direction or the −x-direction) and the second direction (e.g., the y-direction or the −y-direction) in the display area DA (see FIG. 1), a plurality of first bridge portions 12 connecting adjacent ones of the first island portions 11 to each other, and a first protective layer 15.

Each first island portion 11 may be connected to a plurality of first bridge portions 12. For example, each first island portion 11 may be connected to four first bridge portions 12. Two of the four first bridge portions 12 may be respectively arranged on two sides of the first island portion 11 in the first direction (e.g., the x-direction or the −x-direction), and the remaining two of the four first bridge portions 12 may be respectively arranged on two sides of the first island portion 11 in the second direction (e.g., the y-direction or the −y-direction). In an embodiment, the four first bridge portions 12 may be respectively connected to four sides of the first island portion 11. The four first bridge portions 12 may be respectively adjacent to corners of the first island portion 11.

The first bridge portions 12 may be arranged such that the first bridge portions 12 are spaced apart from each other by an opening CS located between the first bridge portions 12. The first bridge portion 12 may have a serpentine shape. For example, as illustrated in FIG. 4A, the first bridge portion 12 may have an approximately letter “S” shape.

The first protective layer 15 may be arranged outside the first island portions 11 and the first bridge portions 12, and may extend along edges of the first island portions 11 and the first bridge portions 12. That is, the first protective layer 15 may be arranged such that the first protective layer 15 covers a side wall defining the opening CS.

Referring to FIG. 4B, the display panel 10 may include a plurality of first island portions 11 spaced apart from each other in the first direction (e.g., the x-direction or the −x-direction) and the second direction (e.g., the y-direction or the −y-direction) in the display area DA (see FIG. 1), a plurality of first bridge portions 12 connecting adjacent ones of the first island portions 11 to each other, and a first protective layer 15. The first bridge portions 12 may be arranged such that the first bridge portions 12 are spaced apart from each other by an opening CS located between the first bridge portions 12.

In an embodiment, at least one of sides of the first island portion 11 may be tilted obliquely with respect to the first direction (e.g., the x-direction or the −x-direction) and/or the second direction (e.g., the y-direction or the −y-direction). FIG. 4B illustrates that all of four sides of the first island portion 11 are tilted obliquely in a clockwise direction.

The first island portion 11 may be connected to a plurality of first bridge portions 12. For example, the first island portion 11 may be connected to four first bridge portions 12. Two of the four first bridge portions 12 may be respectively arranged on two sides of the first island portion 11 in the first direction (e.g., the x-direction or the −x-direction), and the remaining two of the four first bridge portions 12 may be respectively arranged on two sides of the first island portion 11 in the second direction (e.g., the y-direction or the −y-direction).

The first bridge portion 12 may have a serpentine shape. For example, as illustrated in FIG. 4B, the first bridge portion 12 may have an approximately letter “S” shape.

In an embodiment, as illustrated in FIG. 4B, the first bridge portion 12 may extend substantially parallel to a side of an adjacent one of the first island portions 11. For example, the first bridge portion 12 may have two round portions respectively connected to adjacent ones of the first island portions 11, and a straight portion connecting the two round portions to each other. The straight portion of the first bridge portion 12 may extend substantially parallel to a side of an adjacent one of the first island portions 11.

The first protective layer 15 may be arranged outside the first island portions 11 and the first bridge portions 12, and may extend along edges of the first island portions 11 and the first bridge portions 12. That is, the first protective layer 15 may be arranged such that the first protective layer 15 covers a side wall defining the opening CS.

According to the arrangement of the first island portion 11 and/or the structure of the first bridge portion 12 as described herein, the area of the opening CS illustrated in FIG. 4B may be relatively smaller than the area of the opening CS illustrated in FIG. 4A. Thus, the display panel 10 according to the embodiment illustrated in FIG. 4B may provide a relatively high-resolution image.

Referring to FIG. 4C, the display panel 10 may include a plurality of first island portions 11 spaced apart from each other in the first direction (e.g., the x-direction or the −x-direction) and the second direction (e.g., the y-direction or the −y-direction) in the display area DA (see FIG. 1), a plurality of first bridge portions 12 connecting adjacent ones of the first island portions 11 to each other, and a first protective layer 15.

Each first island portion 11 may be connected to a plurality of first bridge portions 12. For example, each first island portion 11 may be connected to four first bridge portions 12. Two of the four first bridge portions 12 may be respectively arranged on two sides of the first island portion 11 in the first direction (e.g., the x-direction or the −x-direction), and the remaining two of the four first bridge portions 12 may be respectively arranged on two sides of the first island portion 11 in the second direction (e.g., the y-direction or the −y-direction). In an embodiment, the four first bridge portions 12 may be respectively connected to four sides of the first island portion 11. The four first bridge portions 12 may be respectively adjacent to corners of the first island portion 11.

The first bridge portions 12 may be spaced apart from each other by an opening CS located between the first bridge portions 12. In an embodiment, an opening CS having an approximately H shape and an opening CS having an approximately I shape, which is obtained by rotating the described H shape by 90 degrees, may be alternately and repeatedly arranged in the first direction (e.g., the x-direction or the −x-direction) and the second direction (e.g., the y-direction or the −y-direction). Two ends of each first bridge portion 12 may be respectively connected to adjacent ones of the first island portions 11, and one side of each first bridge portion 12 may be spaced apart from one side of an adjacent one of the first island portions 11 and/or one side of another first bridge portion 12 by the opening CS.

The first protective layer 15 may be arranged outside the first island portions 11 and the first bridge portions 12, and may extend along edges of the first island portions 11 and the first bridge portions 12. That is, the first protective layer 15 may be arranged such that the first protective layer 15 covers a side wall defining the opening CS.

In an embodiment, the display panel 10 may include a plurality of second island portions spaced apart from each other in the first direction (e.g., the x-direction or the −x-direction) and the second direction (e.g., the y-direction or the −y-direction) in the non-display area NDA (see FIG. 1), and a plurality of second bridge portions connecting adjacent second island portions to each other. Accordingly, the non-display area NDA of the display panel 10 may also be stretched in various directions. The second island portion and the second bridge portion may have the same or similar shapes as the first island portion 11 and the first bridge portion 12 of the display area DA, which have been described with reference to FIGS. 4A to 4C, respectively. In another embodiment, the second island portion and the second bridge portion of the non-display area NDA may have different shapes from the first island portion 11 and the first bridge portion 12 of the display area DA, respectively.

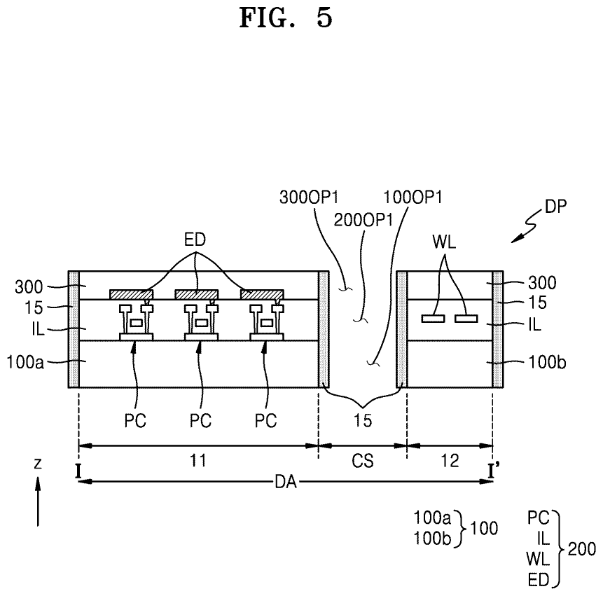

FIG. 5 is a schematic cross-sectional view of the display panel, taken along a line I-I′ of FIG. 4A.

Referring to FIG. 5, the first island portion 11 and the first bridge portion 12 of the display panel 10 may be spaced apart from each other, with the opening CS between the first island portion 11 and the first bridge portion 12. The first island portion 11 may include light-emitting diodes ED and pixel circuits PC electrically connected to the light-emitting diodes ED, and the first bridge portion 12 may include wirings WL electrically connected to the pixel circuits PC arranged in each of adjacent ones of the first island portions 11.

A substrate 100 may include an island area 100a corresponding to the first island portion 11 of the display panel 10 and a bridge area 100b corresponding to the first bridge portion 12 of the display panel 10. The substrate 100 may include polymer resin, such as, for example, polyethersulfone, polyarylate, polyetherimide, polyethylene naphthalate, polyethylene terephthalate, polyphenylene sulfide, polyimide, polycarbonate, cellulose triacetate, or cellulose acetate propionate. In an embodiment, the substrate 100 may be a single layer including the described polymer resin. In another embodiment, the substrate 100 may have a multi-layer structure including at least one base layer including the described polymer resin and at least one barrier layer including an inorganic insulating material. In a plan view, the at least one barrier layer may be arranged to correspond to the island area 100a, and may be spaced apart from the bridge area 100b. The bridge area 100b may include a base layer, without including a barrier layer. For example, because the first bridge portion 12 is subject to relatively high deformation when the display panel 10 is stretched, embodiments of the present disclosure may refrain from including a layer including an inorganic insulating material that is prone to cracking in the bridge area 100b. The substrate 100 including the polymer resin may be flexible, rollable, or bendable.

First, regarding the first island portion 11 of the display panel 10, a display layer 200 including a pixel circuit PC and a light-emitting diode ED may be arranged on the island area 100a of the substrate 100. The display layer 200 may include at least one semiconductor layer and conductive layers that constitute the pixel circuit PC, and an insulating layer IL arranged above and/or below the at least one semiconductor layer and the conductive layers. The insulating layer IL on the island area 100a may include an inorganic insulating layer and/or an organic insulating layer. The light-emitting diode ED may be arranged on the insulating layer IL, and may be electrically connected to a corresponding one of the pixel circuits PC. The light-emitting diodes ED may emit light of different colors or light of the same color. In an embodiment, the light-emitting diodes ED may respectively emit red light, green light, and blue light. In some embodiments, the light-emitting diodes ED may emit white light. In another embodiment, the light-emitting diodes ED may respectively emit red light, green light, blue light, and white light.

In an embodiment, FIG. 5 illustrates three pixel circuits PC arranged in each first island portion 11 and three light-emitting diodes ED respectively connected to the three pixel circuits PC, but the disclosure is not limited thereto. In another embodiment, the number of pixel circuits PC and the number of light-emitting diodes ED arranged in the first island portion 11 may each be one, two, or four or more.

An encapsulation layer 300 may be arranged on the light-emitting diode ED, and may protect the light-emitting diode ED from an external force and/or moisture penetration. The encapsulation layer 300 may include an inorganic encapsulation layer and/or an organic encapsulation layer. In some embodiments, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as, for example, resin. In some embodiments, the encapsulation layer 300 may include urethane, epoxy, and/or acrylate. The encapsulation layer 300 may include a photosensitive material, for example, a photoresist.

Regarding the first bridge portion 12 of the display panel 10, a display layer 200 including wirings WL may be arranged on the bridge area 100b of the substrate 100. The display layer 200 may include a plurality of conductive layers including wirings WL, and an insulating layer IL arranged above and/or below the conductive layers. The insulating layer IL on the bridge area 100b may include an organic insulating layer, without including an inorganic insulating layer. For example, because the first bridge portion 12 is subject to relatively high deformation when the display panel 10 is stretched, embodiments of the present disclosure may refrain from including a layer including an inorganic insulating material that is prone to cracking in the display layer 200 of the first bridge portion 12.

As described herein, the wirings WL of the first bridge portion 12 may each be a signal line (e.g., a gate line, a data line, or the like) configured to provide an electrical signal to a transistor included in the pixel circuit PC of the first island portion 11, or may each be a voltage line (e.g., a power voltage line, an initialization voltage line, or the like) configured to provide a voltage to a transistor included in the pixel circuit PC of the first island portion 11. The encapsulation layer 300 may also be arranged in the first bridge portion 12. In another embodiment, the encapsulation layer 300 may not be present in the first bridge portion 12.

Referring to FIGS. 4A to 4C and 5, the island area 100a of the substrate 100 may correspond to the first island portion 11, the bridge area 100b of the substrate 100 may correspond to the first bridge portion 12, and the island area 100a and the bridge area 100b of the substrate 100 may be connected to each other. The substrate 100 may have (or may define) an opening 100OP1 having the same shape as the opening CS.

Similarly, the display layer 200 arranged on the island area 100a and the display layer 200 arranged on the bridge area 100b may be connected to each other. In other words, the display layer 200 may include an area corresponding to the first island portion 11, an area corresponding to the first bridge portion 12, and an opening 200OP1 having the same shape as the opening CS.

The encapsulation layer 300 arranged on the island area 100a and the encapsulation layer 300 arranged on the bridge area 100b may be connected to each other. In other words, the encapsulation layer 300 may include an area corresponding to the first island portion 11, an area corresponding to the first bridge portion 12, and an opening 300OP1 having the same shape as the opening CS.

In other words, the opening 100OP1 of the substrate 100, the opening 200OP1 of the display layer 200, and the opening 300OP1 of the encapsulation layer 300 may be connected to each other to form the opening CS. The first protective layer 15 may cover a side surface of the substrate 100, which defines the opening 100OP1 of the substrate 100, and a side surface of the display layer 200, which defines the opening 200OP1 of the display layer 200. In an embodiment, the first protective layer 15 may further cover a side surface of the encapsulation layer 300 which defines the opening 300OP1 of the encapsulation layer 300. The first protective layer 15 may extend in the z-direction or −z-direction.

The first protective layer 15 may include an organic insulating material and/or an inorganic insulating material that may be used for conformal coating based on chemical vapor deposition. In an embodiment, the first protective layer 15 may include parylene, silicon oxide (SiOₓ), and/or silicon nitride (SiNₓ).

As the display panel 10 has a higher resolution, the aspect ratio of the opening CS may increase, and the area of the first bridge portion 12 may decrease. In a process of manufacturing the opening CS, the wirings WL of the first bridge portion 12 may be exposed by the opening CS due to a decrease in margin. According to embodiments, by including the first protective layer 15 covering the side surface of the substrate 100 and the side surface of the display layer 200, which form the opening CS, the wirings WL may be prevented from being exposed by the opening CS, and thus, defects during the manufacturing process may be reduced, and a display panel 10 with high reliability may be provided.

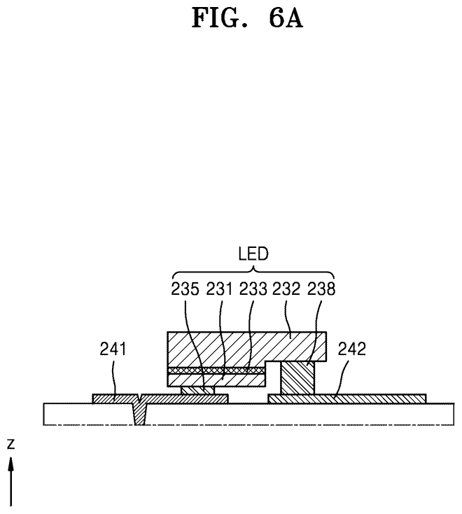

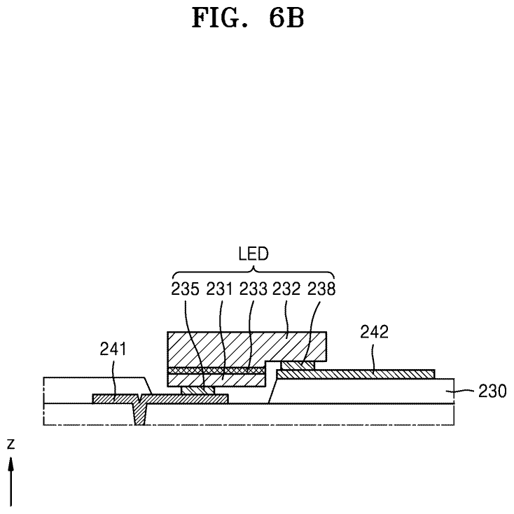

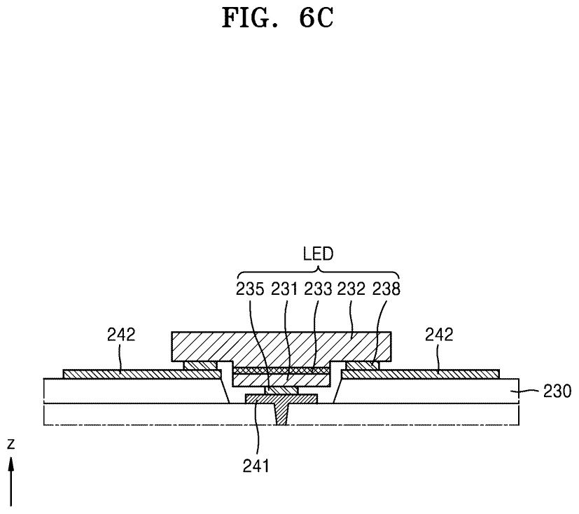

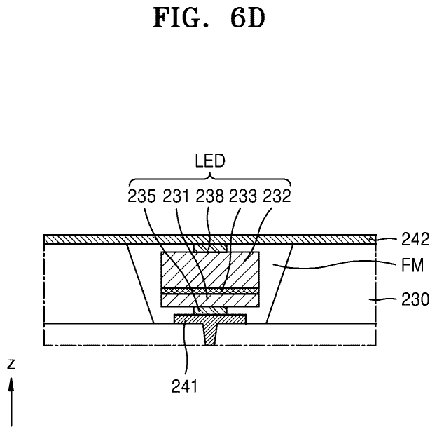

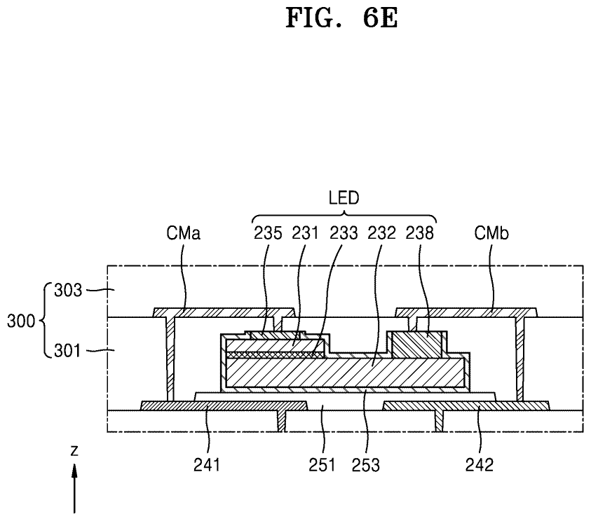

FIGS. 6A to 6E are each a schematic cross-sectional view of a light-emitting diode of a display panel according to an embodiment.

Referring to FIG. 6A, a light-emitting diode LED may include an inorganic light-emitting diode including an inorganic material. The light-emitting diode LED may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the light-emitting diode LED may be respectively and electrically connected to a first electrode pad 241 and a second electrode pad 242, which are arranged on the same layer. The second electrode pad 242 may be a portion of the second voltage line VSSL (see FIG. 3A), or may be a conductive layer electrically connected to the second voltage line VSSL (see FIG. 3A).

In some embodiments, the first semiconductor layer 231 may include a p-type semiconductor layer. The p-type semiconductor layer may include a semiconductor material having a composition formula of InₓAl_{y}Ga_{1-x-y}N (where 0≤x≤1, 0≤y≤1, and 0≤x+y≤1), for example, a semiconductor material selected from GaN, AlN, AlGaN, InGaN, InN, InAlGaN, and AlInN, and may be doped with a p-type dopant, such as, for example, Mg, Zn, Ca, Sr, or Ba.

The second semiconductor layer 232 may include, for example, an n-type semiconductor layer. The n-type semiconductor layer may include a semiconductor material having a composition formula of InₓAl_{y}Ga_{1-x-y}N (where 0≤x≤1, 0≤y≤1, and 0≤x+y≤1), for example, a semiconductor material selected from GaN, AlN, AlGaN, InGaN, InN, InAlGaN, and AlInN, and may be doped with an n-type dopant, such as, for example, Si, Ge, or Sn.

The intermediate layer 233 may be an area in which electrons and holes recombine, may transition to a low energy level as the electrons and holes recombine, and may generate light having a corresponding wavelength. For example, the intermediate layer 233 may include a semiconductor material having a composition formula of InₓAl_{y}Ga_{1-x-y}N (where 0≤x≤1, 0≤y≤1, and 0≤x+y≤1), and may be formed in a single quantum well structure or a multi quantum well (MQW) structure. In some aspects, the intermediate layer 233 may include a quantum wire structure or a quantum dot structure.

FIG. 6A illustrates that the first semiconductor layer 231 includes a p-type semiconductor layer and the second semiconductor layer 232 includes an n-type semiconductor layer, but the disclosure is not limited thereto. In another embodiment, the first semiconductor layer 231 may include an n-type semiconductor layer, and the second semiconductor layer 232 may include a p-type semiconductor layer.

FIG. 6A illustrates that the first electrode pad 241 and the second electrode pad 242 are arranged on the same layer, but the disclosure is not limited thereto. Referring to FIG. 6B, the first electrode pad 241 and the second electrode pad 242 may be arranged on different layers. For example, a bank layer 230 having an opening overlapping at least a portion of the first electrode pad 241 may be arranged on the first electrode pad 241, and the second electrode pad 242 may be arranged on an upper surface of the bank layer 230. The structure of the light-emitting diode LED illustrated in FIG. 6B is the same as that described herein with reference to FIG. 6A.

In another embodiment, as illustrated in FIG. 6C, the second electrode pad 242 may be arranged on two sides of the first electrode pad 241 in a cross-sectional view. The bank layer 230 may include an opening overlapping at least a portion of the first electrode pad 241, and the second electrode pad 242 may be arranged around the opening of the bank layer 230. In some embodiments, in a plan view, the second electrode pad 242 may have a closed loop shape that entirely surrounds the opening of the bank layer 230 and/or the first electrode pad 241. The structure of the light-emitting diode LED illustrated in FIG. 6C is the same as that described herein with reference to FIG. 6A.

FIGS. 6A to 6C show that the first electrode 235 and the second electrode 238 of the light-emitting diode LED face the same direction (e.g., a downward direction or a −z-direction), but the disclosure is not limited thereto. As illustrated in FIG. 6D, the first electrode 235 and the second electrode 238 of the light-emitting diode LED may face opposite directions.

The bank layer 230 may include an opening exposing at least a portion of the first electrode pad 241, and the thickness of the bank layer 230 may be substantially the same as the thickness of the light-emitting diode LED. The opening of the bank layer 230 may be filled with a filling material, and the second electrode pad 242 may be arranged on an upper surface of the bank layer 230 so as to be electrically connected to (e.g., be in contact with) the second electrode 238 of the light-emitting diode LED. The filling material may be an organic material having insulating properties.

In another embodiment, as illustrated in FIG. 6E, the first electrode 235 and the second electrode 238 of the light-emitting diode LED may face the same direction, but may face a +z-direction. The light-emitting diode LED may be attached onto the first electrode pad 241 and the second electrode pad 242 by using an adhesive layer 251. A first encapsulation layer 301 may be arranged on the first electrode pad 241, the second electrode pad 242, and the light-emitting diode LED. In an embodiment, a light-emitting diode protection layer 253 may be arranged between the light-emitting diode LED and the first encapsulation layer 301. The light-emitting diode protection layer 253 may include an organic insulating material and/or an inorganic insulating material. In an embodiment, the light-emitting diode protection layer 253 may include polyimide.

A first contact electrode CMa and a second contact electrode CMb may be arranged on the first encapsulation layer 301. Each of the first contact electrode CMa and the second contact electrode CMb may include a conductive material including molybdenum (Mo), aluminum (Al), copper (Cu), titanium (Ti), or the like, and may be formed as a multi-layer or a single layer including the described material. The first contact electrode CMa may electrically connect the first electrode pad 241 and the first electrode 235 of the light-emitting diode LED to each other through contact holes penetrating the first encapsulation layer 301. The second contact electrode CMb may electrically connect the second electrode pad 242 and the second electrode 238 of the light-emitting diode LED to each other through contact holes penetrating the first encapsulation layer 301.

A second encapsulation layer 303 may be arranged on the first contact electrode CMa and the second contact electrode CMb. Each of the first encapsulation layer 301 and the second encapsulation layer 303 may include a structure in which an inorganic encapsulation layer including an inorganic insulating material, an organic encapsulation layer including an organic insulating material, and an inorganic encapsulation layer including an inorganic insulating material are stacked. In another embodiment, each of the first encapsulation layer 301 and the second encapsulation layer 303 may include an organic material, such as, for example, resin.

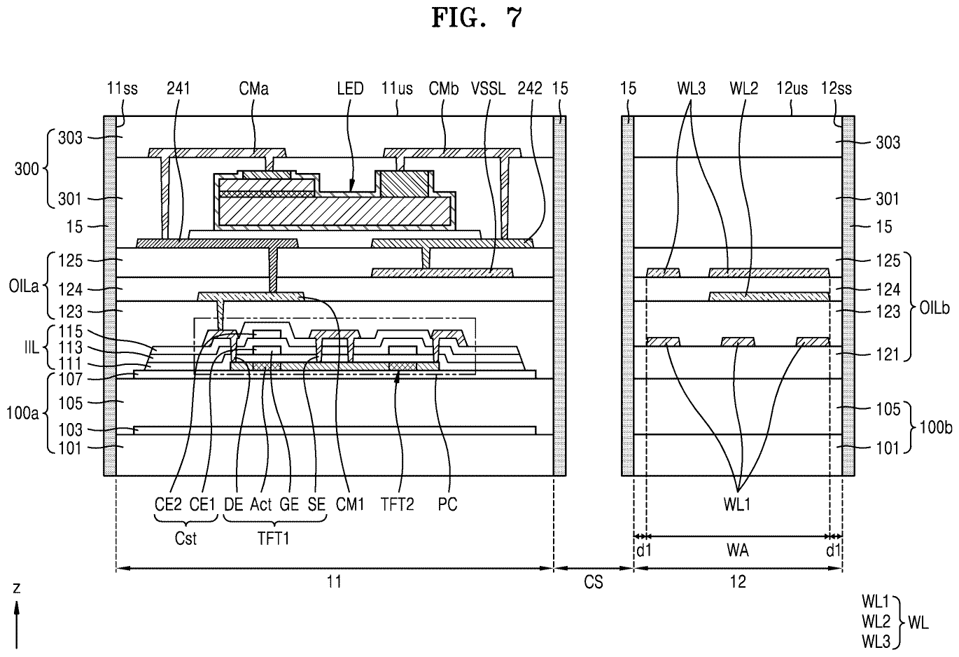

FIG. 7 is a schematic cross-sectional view of a portion of a display area of a display panel according to an embodiment.

Referring to FIG. 7, the first island portion 11 and the first bridge portion 12 of the display panel 10 may be spaced apart from each other, with the opening CS between the first island portion 11 and the first bridge portion 12. The first island portion 11 may include a light-emitting diode LED and a pixel circuit PC electrically connected to the light-emitting diode LED, and the first bridge portion 12 may include wirings WL electrically connected to the pixel circuit PC arranged in the first island portion 11.

The substrate 100 may include an island area 100a corresponding to the first island portion 11 of the display panel 10 and a bridge area 100b corresponding to the first bridge portion 12 of the display panel 10. In an embodiment, the substrate 100 may have a multi-layer structure including first base layer 101 and second base layer 105 each including polymer resin, and first barrier layer 103 and second barrier layer 107 each including an inorganic insulating material. For example, the substrate 100 may include the first base layer 101, the second base layer 105 on the first base layer 101, the first barrier layer 103 between the first base layer 101 and the second base layer 105, and the second barrier layer 107 on the second base layer 105. Each of the first base layer 101 and the second base layer 105 may include polymer resin, and each of the first barrier layer 103 and the second barrier layer 107 may include an inorganic insulating material. Each of the first barrier layer 103 and the second barrier layer 107 may have an isolated shape arranged in the first island portion 11. That is, in a plan view, the first barrier layer 103 and the second barrier layer 107 may not overlap the bridge area 100b.

First, regarding the first island portion 11, the pixel circuit PC may be arranged on the second barrier layer 107. The pixel circuit PC may include a first thin-film transistor TFT1, a second thin-film transistor TFT2, and a storage capacitor Cst. Each of the first thin-film transistor TFT1 and the second thin-film transistor TFT2 may include a semiconductor layer Act, a gate electrode GE, a source electrode SE, and a drain electrode DE. In an embodiment, the first thin-film transistor TFT1 may be a driving transistor, and the second thin-film transistor TFT2 may be a switching transistor. Although FIG. 7 illustrates that each of the first thin-film transistor TFT1 and the second thin-film transistor TFT2 is of a top-gate type in which the gate electrode GE is arranged on the semiconductor layer Act, with a gate insulating layer 111 between the gate electrode GE and the semiconductor layer Act, in another embodiment, each of the first thin-film transistor TFT1 and the second thin-film transistor TFT2 may be of a bottom-gate type.

Inorganic insulating layers constituting an inorganic insulating stack IIL may be arranged between the semiconductor layer Act and conductive layers that constitute the pixel circuit PC. The inorganic insulating stack IIL may include a gate insulating layer 111, a first interlayer insulating layer 113, and a second interlayer insulating layer 115. Each of the gate insulating layer 111, the first interlayer insulating layer 113, and the second interlayer insulating layer 115 may include an inorganic insulating material, such as, for example, silicon oxide, silicon nitride, silicon oxynitride, aluminum oxide, or titanium oxide, and may be a single layer or multi-layer including the described material.

The semiconductor layer Act may include polysilicon. Alternatively, the semiconductor layer Act may include amorphous silicon, an oxide semiconductor, an organic semiconductor, or the like. The gate electrode GE may include a metal thin film including a low-resistance metal material. The gate electrode GE may include a conductive material including molybdenum (Mo), aluminum (Al), copper (Cu), titanium (Ti), or the like, and may be formed as a multi-layer or a single layer including the described material. For example, the gate electrode GE may include a metal thin film including three layers having a Ti/Al/Ti structure. The gate insulating layer 111 may be arranged between the semiconductor layer Act and the gate electrode GE.

The source electrode SE and the drain electrode DE may be arranged on the same layer, for example, the second interlayer insulating layer 115, and may include the same material. Each of the source electrode SE and the drain electrode DE may include a metal thin film including a low-resistance metal material. Each of the source electrode SE and the drain electrode DE may include a conductive material including molybdenum (Mo), aluminum (Al), copper (Cu), titanium (Ti), or the like, and may be formed as a multi-layer or a single layer including the described material. For example, like the gate electrode GE, each of the source electrode SE and the drain electrode DE may include a metal thin film including three layers having a Ti/Al/Ti structure.

The storage capacitor Cst may include a first electrode CE1 and a second electrode CE2 that overlap each other, with the first interlayer insulating layer 113 between the first electrode CE1 and the second electrode CE2. The storage capacitor Cst may overlap the first thin-film transistor TFT1. In this regard, FIG. 7 illustrates that the gate electrode GE of the first thin-film transistor TFT1 is provided as a single body with the first electrode CE1 of the storage capacitor Cst. In another embodiment, the storage capacitor Cst may not overlap the first thin-film transistor TFT1. The storage capacitor Cst may be covered by the second interlayer insulating layer 115.

The second electrode CE2 of the storage capacitor Cst may include a conductive material, and may be formed as a multi-layer or a single layer. The second electrode CE2 may include a metal thin film including a low-resistance metal material. The second electrode CE2 may include a conductive material including molybdenum (Mo), aluminum (Al), copper (Cu), titanium (Ti), or the like, and may be formed as a multi-layer or a single layer including the described material. For example, the second electrode CE2 may be provided as a metal thin film including three layers having a Ti/Al/Ti structure.

A first organic insulating stack OILa may be arranged on the inorganic insulating stack IIL. The first organic insulating stack OILa may include a first organic insulating layer 123, a second organic insulating layer 124, and a third organic insulating layer 125. Each of the first organic insulating layer 123, the second organic insulating layer 124, and the third organic insulating layer 125 may include an organic insulating material, and may be formed as a multi-layer or a single layer.

The first organic insulating layer 123 may be arranged on the source electrode SE and the drain electrode DE. A third contact electrode CM1 may be arranged on the first organic insulating layer 123. The third contact electrode CM1 may be electrically connected to the drain electrode DE of the first thin-film transistor TFT1 through a contact hole penetrating the first organic insulating layer 123. The third contact electrode CM1 may include a conductive material including molybdenum (Mo), aluminum (Al), copper (Cu), titanium (Ti), or the like, and may be formed as a multi-layer or a single layer including the described material.

The second organic insulating layer 124 may be arranged on the third contact electrode CM1, and the second voltage line VSSL may be arranged on the second organic insulating layer 124. The second voltage line VSSL may be electrically connected to the second electrode of the light-emitting diode LED to supply the second power voltage VSS thereto. The second voltage line VSSL may include a conductive material including molybdenum (Mo), aluminum (Al), copper (Cu), titanium (Ti), or the like, and may be formed as a multi-layer or a single layer including the described material.

The third organic insulating layer 125 may be arranged on the second voltage line VSSL, and the first electrode pad 241 and the second electrode pad 242 may be arranged on the third organic insulating layer 125. The first electrode pad 241 may be electrically connected to the third contact electrode CM1 through a contact hole penetrating the second organic insulating layer 124 and the third organic insulating layer 125. The second electrode pad 242 may be electrically connected to the second voltage line VSSL through a contact hole penetrating the third organic insulating layer 125.

The light-emitting diode LED may be arranged on the first electrode pad 241 and the second electrode pad 242. The structure of the light-emitting diode LED is the same as that described herein with reference to FIG. 6E. The light-emitting diode LED may be attached onto the first electrode pad 241 and the second electrode pad 242 by using the adhesive layer 251 (see FIG. 6E).

The encapsulation layer 300 may be arranged on the first electrode pad 241, the second electrode pad 242, and the light-emitting diode LED. The encapsulation layer 300 may include a first encapsulation layer 301 and a second encapsulation layer 303.

The first contact electrode CMa and the second contact electrode CMb may be arranged on the first encapsulation layer 301. The first contact electrode CMa may electrically connect the first electrode pad 241 and the first electrode 235 of the light-emitting diode LED to each other through contact holes penetrating the first encapsulation layer 301. The second contact electrode CMb may electrically connect the second electrode pad 242 and the second electrode 238 of the light-emitting diode LED to each other through contact holes penetrating the first encapsulation layer 301. That is, the first electrode 235 of the light-emitting diode LED may be electrically connected to the pixel circuit PC through the first contact electrode CMa, the first electrode pad 241, and the third contact electrode CM1. The second electrode 238 of the light-emitting diode LED may be electrically connected to the second voltage line VSSL through the second contact electrode CMb and the second electrode pad 242.

The second encapsulation layer 303 may be arranged on the first contact electrode CMa and the second contact electrode CMb. Each of the first encapsulation layer 301 and the second encapsulation layer 303 may include a structure in which an inorganic encapsulation layer including an inorganic insulating material, an organic encapsulation layer including an organic insulating material, and an inorganic encapsulation layer including an inorganic insulating material are stacked. In another embodiment, each of the first encapsulation layer 301 and the second encapsulation layer 303 may include an organic material, such as, for example, resin.

The first island portion 11 of the display panel 10 may represent a stacked structure from the island area 100a of the substrate 100 to the encapsulation layer 300 arranged on the island area 100a. In the present specification, an upper surface refers to a surface on which an image is displayed in the display panel 10, that is, a surface facing the substrate 100. In FIG. 7, an upper surface 11us of the first island portion 11 may be an upper surface of the second encapsulation layer 303. A side surface 11ss of the first island portion 11 refers to a surface exposed by the opening CS. As illustrated in FIG. 7, a side surface of the island area 100a, a side surface of the first organic insulating stack OILa, and a side surface of the encapsulation layer 300 may form the side surface 11ss of the first island portion 11.

Regarding the first bridge portion 12, base layers may be arranged in the bridge area 100b of the substrate 100, without barrier layers. For example, the first base layer 101 and the second base layer 105 may be arranged in the bridge area 100b, and in a plan view, the first barrier layer 103 and the second barrier layer 107 may be spaced apart from the bridge area 100b such that the first barrier layer 103 and the second barrier layer 107 do not overlap the bridge area 100b.

A second organic insulating stack OILb may be arranged on the bridge area 100b of the substrate 100. The second organic insulating stack OILb may include a first organic insulating layer 123, a second organic insulating layer 124, a third organic insulating layer 125, and a fourth organic layer 121. The first organic insulating layer 123, the second organic insulating layer 124, and the third organic insulating layer 125 of the second organic insulating stack OILb may be formed through the same process as the first organic insulating layer 123, the second organic insulating layer 124, and the third organic insulating layer 125 of the first organic insulating stack OILa. Because the bridge area 100b does not include the inorganic insulating stack IIL, the second organic insulating stack OILb may further include the fourth organic layer 121 of which an upper surface is on the same level as an upper surface of the inorganic insulating stack IIL. In an embodiment, the first island portion 11 may further include the fourth organic layer 121, and the fourth organic layer 121 may be arranged such that the fourth organic layer 121 covers a side surface of the inorganic insulating stack IIL having an isolated shape. The fourth organic layer 121 may include an organic insulating material, and may be formed as a multi-layer or a single layer.

First wirings WL1 may be arranged on the fourth organic layer 121, a second wiring WL2 may be arranged on the first organic insulating layer 123, and third wirings WL3 may be arranged on the second organic insulating layer 124. Each of the first wirings WL1, the second wiring WL2, and the third wirings WL3 may be, as described herein, a signal line (e.g.. a gate line, a data line, or the like) configured to provide an electrical signal to a transistor included in the pixel circuit PC of the first island portion 11, or may be a voltage line (e.g., a power voltage line, an initialization voltage line, or the like) configured to provide a voltage to a transistor included in the pixel circuit PC of the first island portion 11. Each of the wirings WL may include a conductive material including molybdenum (Mo), aluminum (Al), copper (Cu), titanium (Ti), or the like, and may be formed as a multi-layer or a single layer including the described material.

The wirings WL may be arranged in a wiring area WA. The width of the wiring area WA may be less than the width of the bridge area 100b. For example, an edge of the wiring area WA may be separated inward from an edge of the bridge area 100b. FIG. 7 illustrates that two edges of the wiring area WA are respectively separated inward from two edges of the bridge area 100b by a first distance d1.

The encapsulation layer 300 may be arranged on the second organic insulating stack OILb. The encapsulation layer 300 may include a first encapsulation layer 301 and a second encapsulation layer 303. Each of the first encapsulation layer 301 and the second encapsulation layer 303 may include a structure in which an inorganic encapsulation layer including an inorganic insulating material, an organic encapsulation layer including an organic insulating material, and an inorganic encapsulation layer including an inorganic insulating material are stacked. In another embodiment, each of the first encapsulation layer 301 and the second encapsulation layer 303 may include an organic material, such as, for example, resin.

The first bridge portion 12 of the display panel 10 may represent a stacked structure from the bridge area 100b of the substrate 100 to the encapsulation layer 300 arranged on the bridge area 100b. An upper surface 12us of the first bridge portion 12 may be an upper surface of the second encapsulation layer 303. A side surface 12ss of the first bridge portion 12 refers to a surface exposed by the opening CS. As illustrated in FIG. 7, a side surface of the bridge area 100b, a side surface of the second organic insulating stack OILb, and a side surface of the encapsulation layer 300 may form the side surface 12ss of the first bridge portion 12.

The first protective layer 15 may be arranged such that the first protective layer 15 covers the side surface 11ss of the first island portion 11 and the side surface 12ss of the first bridge portion 12. The first protective layer 15 may be deposited on the upper surface 11us and the side surface 11ss of the first island portion 11 and the upper surface 12us and the side surface 12ss of the first bridge portion 12 by using conformal coating based on chemical vapor deposition. Thereafter, a portion of the first protective layer 15 may be etched and removed to expose the upper surface of the second encapsulation layer 303. Accordingly, in a plan view, the first protective layer 15 may be arranged such that the first protective layer 15 is spaced apart from a pixel (or light-emitting diode LED) arranged in the first island portion 11. Because the first protective layer 15 is not arranged on the upper surface 11us of the first island portion 11 and the upper surface 12us of the first bridge portion 12, even when the first protective layer 15 includes an inorganic insulating material, damage to wirings WL or organic insulating layers due to cracks in the first protective layer 15 may be reduced or prevented.

As the display panel 10 has a higher resolution, the aspect ratio of the opening CS may increase, and defects in which the wirings WL are exposed by the opening CS may occur. The first protective layer 15 may cover the side surface 11ss of the first island portion 11 and the side surface 12ss of the first bridge portion 12, thereby preventing the wirings WL from being exposed. Therefore, the width of the wiring area WA in which the wirings WL are arranged may increase. In some aspects, the first protective layer 15 may alleviate stress that is accumulated in the first bridge portion 12 when the display panel 10 is stretched, thereby improving the elongation of the display panel 10.

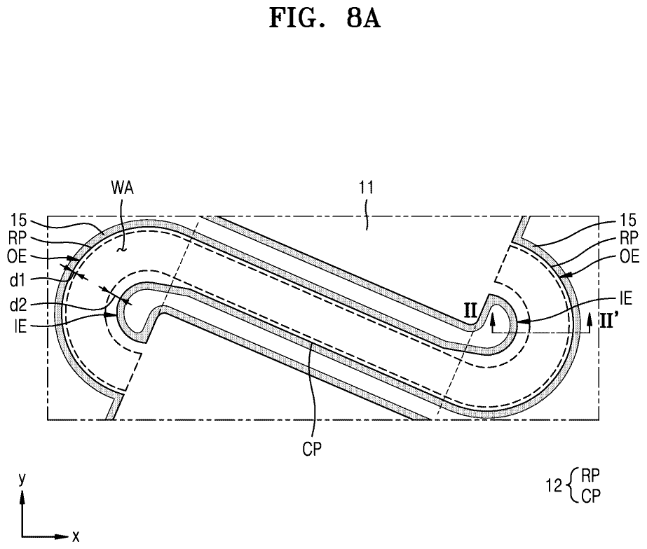

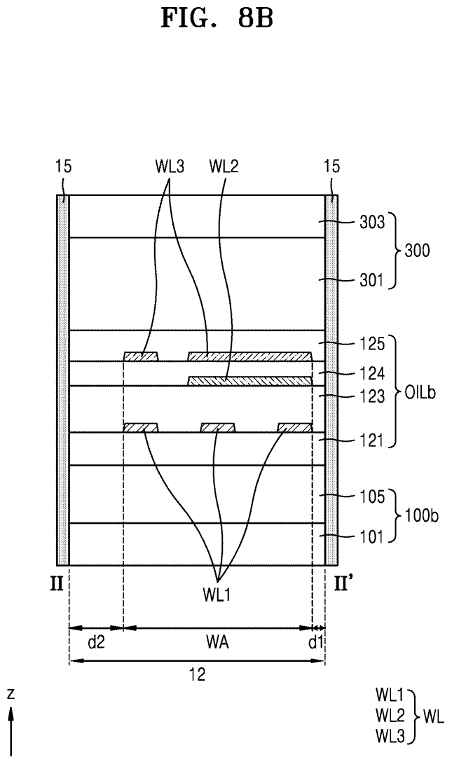

FIG. 8A is a schematic plan view of a bridge portion of a display panel according to an embodiment, and FIG. 8B is a schematic cross-sectional view of the bridge portion, taken along a line II-II′ of FIG. 8A.

Referring to FIGS. 8A and 8B, the first bridge portion 12 may have a serpentine shape (e.g., an approximately letter “S” shape). The first bridge portion 12 may be arranged in a gap between two adjacent ones of the first island portions 11.

The first bridge portion 12 may include two round portions RP and a connection portion CP connecting the two round portions RP to each other. Each of the round portions RP may have an approximately circular arc shape, and may be connected to an edge of the first island portion 11. The connection portion CP may have a substantially straight line shape extending in a direction that is oblique to the first direction (e.g., the x-direction or the −x-direction) and the second direction (e.g., the y-direction or the −y-direction). In an embodiment, the first island portion 11 may be tilted obliquely with respect to the first direction (e.g., the x-direction or the −x-direction) and/or the second direction (e.g., the y-direction or the −y-direction). In this case, the connection portion CP may extend substantially parallel to a side of an adjacent one of the first island portions 11.

Each of the round portions RP may have an inner edge IE and an outer edge OE. The inner edge IE may extend along an arc of an imaginary circle having a first radius. The outer edge OE may extend along an arc of an imaginary circle having a second radius that is greater than the first radius. One end of the inner edge IE may be connected to an edge of the connection portion CP, and the other end of the inner edge IE may be connected to an edge of the first island portion 11. One end of the outer edge OE may be connected to the edge of the connection portion CP, and the other end of the outer edge OE may be connected to the edge of the first island portion 11.

The first bridge portion 12 may have a wiring area WA in which the wirings WL (see FIG. 7) are arranged. The wiring area WA may extend approximately along a central portion of the first bridge portion 12. The width of the wiring area WA may be less than the width of the first bridge portion 12. In an embodiment, the wiring area WA may be separated inward from edges of the first bridge portion 12 to prevent the wirings WL from being exposed by the opening CS. An edge of the first bridge portion 12 may coincide with an edge of the bridge area 100b. An edge of the wiring area WA in the connection portion CP may be separated inward from an edge of the first bridge portion 12 by a first distance d1. An edge of the wiring area WA in the round portion RP may be separated inward from the outer edge OE of the first bridge portion 12 by the first distance d1. The edge of the wiring area WA in the round portion RP may be separated inward from the inner edge IE of the first bridge portion 12 by a second distance d2. The second distance d2 may be greater than the first distance d1.

When the display panel 10 is stretched, more stress may be accumulated on the inner edge IE of each of the round portions RP than on the outer edge OE of each of the round portions RP. Accordingly, by arranging the wirings WL closer to the outer edge OE of each of the round portions RP, the occurrence of cracks may be reduced or prevented.

The first protective layer 15 may extend along an edge of the first island portion 11 and an edge of the first bridge portion 12. That is, the first protective layer 15 may be arranged such that the first protective layer 15 covers the side surface 11ss of the first island portion 11 and the side surface 12ss of the first bridge portion 12, which define the opening CS, as described with reference to FIG. 7. The first protective layer 15 may expose the upper surface 11us of the first island portion 11 and the upper surface 12us of the first bridge portion 12.

As the display panel 10 has a higher resolution, the width of the first bridge portion 12 may decrease. As a distance between a boundary of the wiring area WA and an edge of the first bridge portion 12 decreases, a margin during an etching process may decrease. The first protective layer 15 may cover the side surface 12ss of the first bridge portion 12, thereby preventing the wirings WL from being exposed by the opening CS. Accordingly, by reducing the distance between the boundary of the wiring area WA and the edge of the first bridge portion 12, that is, the first distance d1 and the second distance d2, the width of the wiring area WA may be sufficiently secured. In some aspects, because the first protective layer 15 has a higher modulus than the bridge area 100b of the substrate 100 and the first organic insulating stack OILa, stress accumulated on the inner edge IE of the round portion RP may be dispersed.

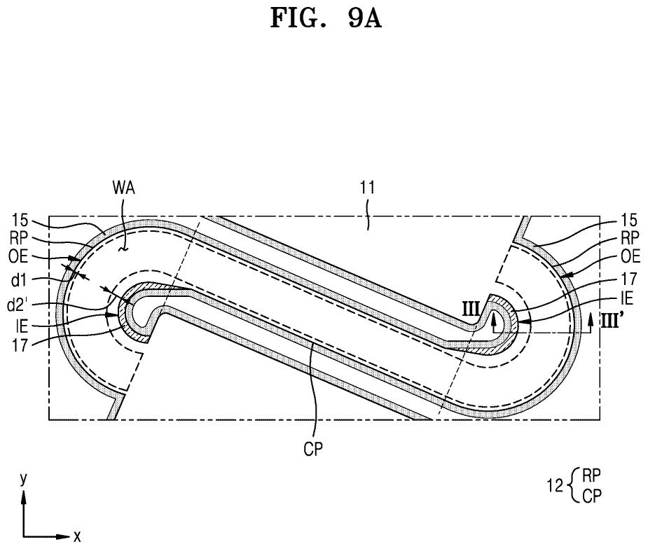

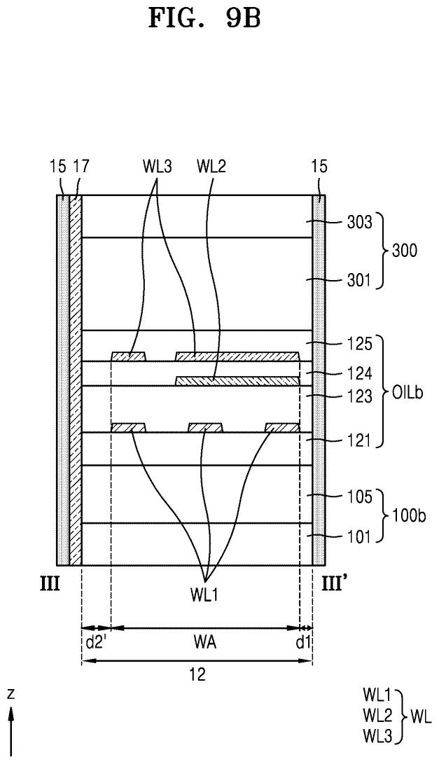

FIG. 9A is a schematic plan view of a bridge portion of a display panel according to an embodiment, and FIG. 9B is a schematic cross-sectional view of the bridge portion, taken along a line III-III′ of FIG. 9A.

Referring to FIGS. 9A and 9B, the first bridge portion 12 may have a serpentine shape (e.g., an approximately letter “S” shape). The first bridge portion 12 may be arranged in a gap between two adjacent ones of the first island portions 11.

The first bridge portion 12 may include two round portions RP and a connection portion CP connecting the two round portions RP to each other. Each of the round portions RP may have an approximately circular arc shape, and may be connected to an edge of the first island portion 11. The connection portion CP may have a substantially straight line shape extending in a direction that is oblique to the first direction (e.g., the x-direction or the −x-direction) and the second direction (e.g., the y-direction or the −y-direction).

Each of the round portions RP may have an inner edge IE and an outer edge OE. The inner edge IE may extend along an arc of an imaginary circle having a first radius. The outer edge OE may extend along an arc of an imaginary circle having a second radius that is greater than the first radius. One end of the inner edge IE may be connected to an edge of the connection portion CP, and the other end of the inner edge IE may be connected to an edge of the first island portion 11. One end of the outer edge OE may be connected to an edge of the connection portion CP, and the other end of the outer edge OE may be connected to an edge of the first island portion 11.

The first bridge portion 12 may have a wiring area WA in which the wirings WL (see FIG. 7) are arranged. The wiring area WA may extend approximately along a central portion of the first bridge portion 12. The width of the wiring area WA may be less than the width of the first bridge portion 12.

An edge of the wiring area WA in the connection portion CP may be separated inward from an edge of the first bridge portion 12 by a first distance d1. An edge of the wiring area WA in the round portion RP may be separated inward from the outer edge OE of the first bridge portion 12 by the first distance d1. The edge of the wiring area WA in the round portion RP may be separated inward from the inner edge IE of the first bridge portion 12 by a second′ distance d2′. The second′ distance d2′ may be greater than the first distance d1.

The first protective layer 15 may extend along an edge of the first island portion 11 and an edge of the first bridge portion 12. That is, the first protective layer 15 may be arranged such that the first protective layer 15 covers the side surface 12ss of the first bridge portion 12. In this case, the first protective layer 15 may expose the upper surface 12us of the first bridge portion 12.

A second protective layer 17 may be arranged between the first protective layer 15 and the inner edge IE of the first bridge portion 12. The second protective layer 17 may extend along the inner edge IE of the first bridge portion 12. The second protective layer 17 may be arranged such that the second protective layer 17 covers the side surface 12ss of the first bridge portion 12. The second protective layer 17 may include an organic insulating material and/or an inorganic insulating material that may be used for conformal coating based on chemical vapor deposition. In an embodiment, the second protective layer 17 may include parylene, silicon oxide (SiOₓ), and/or silicon nitride (SiNₓ).

In an embodiment, a material constituting the second protective layer 17 may be different from a material constituting the first protective layer 15. The modulus of the second protective layer 17 may be higher than the modulus of the first protective layer 15. By arranging the second protective layer 17 having a relatively high modulus between the inner edge IE of the first bridge portion 12 and the first protective layer 15, stress that is accumulated when the display panel 10 is stretched may be dispersed. Accordingly, by further reducing the second′ distance d2′ between the wiring area WA and the inner edge IE of the first bridge portion 12, the width of the wiring area WA in which the wirings WL are arranged may be sufficiently secured.

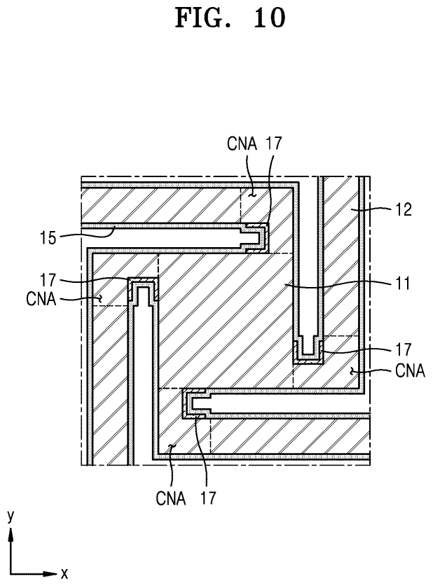

FIG. 10 is a schematic plan view of a display area of a display panel according to an embodiment.

Referring to FIG. 10, the first bridge portion 12 may have a serpentine shape. The first bridge portion 12 may be arranged in a gap between two adjacent ones of the first island portions 11.

The first bridge portion 12 may include two corner areas CNA and a connection portion connecting the two corner areas CNA to each other. Each of the corner areas CNA may include a first portion extending from the first island portion 11 in the first direction (e.g., the x-direction or the −x-direction) or the second direction (e.g., the y-direction or the −y-direction), and a second portion connected to the first portion and extending in the second direction (e.g., the y-direction or the −y-direction) or the first direction (e.g., the x-direction or the −x-direction). In an embodiment, the corner area CNA may be an area in which two portions extending in orthogonal directions are connected to each other.

The first protective layer 15 may extend along an edge of the first island portion 11 and an edge of the first bridge portion 12. That is, the first protective layer 15 may be arranged such that the first protective layer 15 covers the side surface 11ss of the first island portion 11 and the side surface 12ss of the first bridge portion 12, which define the opening CS, as described with reference to FIG. 7. The first protective layer 15 may expose the upper surface 11us of the first island portion 11 and the upper surface 12us of the first bridge portion 12.

The corner area CNA may have an inner edge and an outer edge that are adjacent to the first island portion 11 to which the first bridge portion 12 is connected. The second protective layer 17 may be arranged along the inner edge of the corner area CNA. In an embodiment, the second protective layer 17 may extend along the inner edge of the corner area CNA and a portion of an edge of an adjacent one of the first island portions 11, and may have an approximately letter “C” shape in a plan view. The second protective layer 17 may be arranged between the first protective layer 15 and the side surface 12ss of the first bridge portion 12.

In an embodiment, the modulus of the second protective layer 17 may be higher than the modulus of the first protective layer 15. By arranging the second protective layer 17 having a relatively high modulus between the inner edge IE of the first bridge portion 12 and the first protective layer 15, stress that is accumulated when the display panel 10 is stretched may be dispersed.

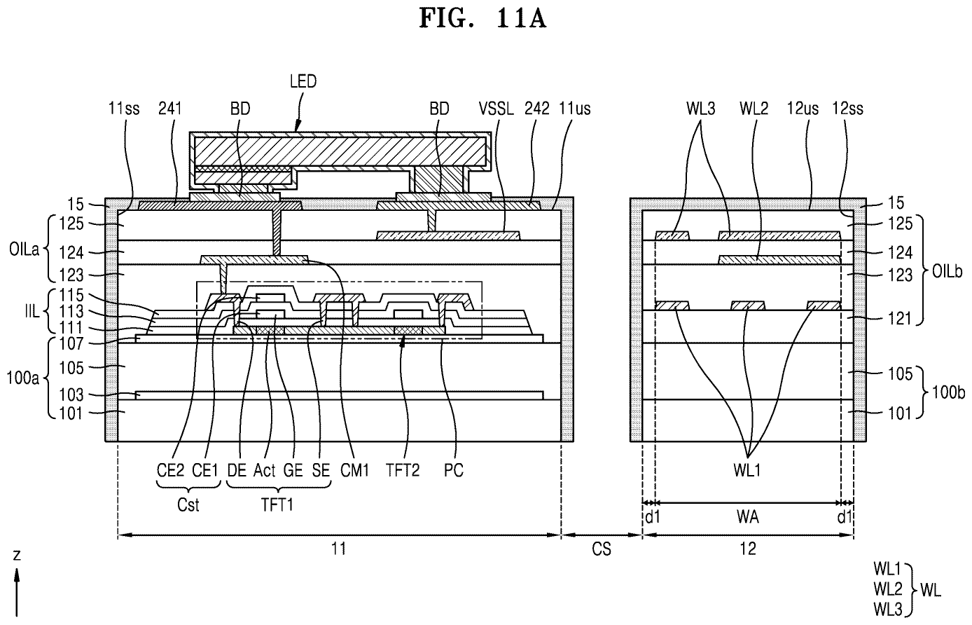

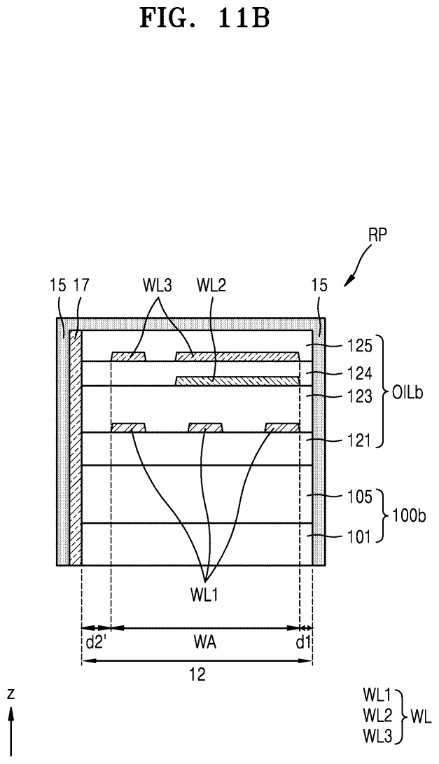

FIG. 11A is a schematic cross-sectional view of a portion of a display area of a display panel according to an embodiment, and FIG. 11B is a schematic cross-sectional view of a portion of a bridge portion of the display panel of FIG. 11A.

FIGS. 11A and 11B are similar to FIGS. 7 and 9B, respectively, but there is a difference in that the first protective layer 15 is arranged such that the first protective layer 15 covers an upper surface of the first organic insulating stack OILa. Hereinafter, descriptions of the same or similar components will be omitted, and differences will be mainly described.

Referring to FIGS. 11A and 11B, the first island portion 11 and the first bridge portion 12 of the display panel 10 may be spaced apart from each other, with the opening CS between the first island portion 11 and the first bridge portion 12. The first island portion 11 may include a light-emitting diode LED and a pixel circuit PC electrically connected to the light-emitting diode LED, and the first bridge portion 12 may include wirings WL electrically connected to the pixel circuit PC arranged in the first island portion 11.

The substrate 100 may include an island area 100a corresponding to the first island portion 11 of the display panel 10 and a bridge area 100b corresponding to the first bridge portion 12 of the display panel 10. Inorganic insulating layers constituting an inorganic insulating stack IIL may be arranged between the semiconductor layer Act and conductive layers that constitute the pixel circuit PC. The inorganic insulating stack IIL may include a gate insulating layer 111, a first interlayer insulating layer 113, and a second interlayer insulating layer 115.

The first organic insulating stack OILa may be arranged on the inorganic insulating stack IIL. The first organic insulating stack OILa may include a first organic insulating layer 123, a second organic insulating layer 124, and a third organic insulating layer 125.

The first organic insulating layer 123 may be arranged on the source electrode SE and the drain electrode DE. The third contact electrode CM1 may be arranged on the first organic insulating layer 123. The third contact electrode CM1 may be electrically connected to the drain electrode DE of the first thin-film transistor TFT1 through a contact hole penetrating the first organic insulating layer 123.

The second organic insulating layer 124 may be arranged on the third contact electrode CM1, and the second voltage line VSSL may be arranged on the second organic insulating layer 124. The second voltage line VSSL may be electrically connected to the second electrode of the light-emitting diode LED to supply the second power voltage VSS thereto.

The third organic insulating layer 125 may be arranged on the second voltage line VSSL, and the first electrode pad 241 and the second electrode pad 242 may be arranged on the third organic insulating layer 125. The first electrode pad 241 may be electrically connected to the third contact electrode CM1 through a contact hole penetrating the second organic insulating layer 124 and the third organic insulating layer 125. The second electrode pad 242 may be electrically connected to the second voltage line VSSL through a contact hole penetrating the third organic insulating layer 125.

The light-emitting diode LED may be arranged on the first electrode pad 241 and the second electrode pad 242. The structure of the light-emitting diode LED is the same as that described herein with reference to FIG. 6A.

The first electrode 235 (see FIG. 6A) of the light-emitting diode LED may be attached to the first electrode pad 241 through a bonding layer BD, and the second electrode 238 (see FIG. 6A) of the light-emitting diode LED may be attached to the second electrode pad 242 through the bonding layer BD. The bonding layer BD may include copper (Cu), indium (In), gold (Au), tin (Sn), or an alloy thereof. In an embodiment, the bonding layer BD may include a conductive composite material including conductive particles, metal nanostructures, and/or an elastomer.

Regarding the first bridge portion 12, base layers may be arranged in the bridge area 100b of the substrate 100, without barrier layers. For example, the first base layer 101 and the second base layer 105 may be arranged in the bridge area 100b, and in a plan view, the first barrier layer 103 and the second barrier layer 107 may be spaced apart from the bridge area 100b such that the first barrier layer 103 and the second barrier layer 107 do not overlap the bridge area 100b.

The second organic insulating stack OILb may be arranged on the bridge area 100b of the substrate 100. The second organic insulating stack OILb may include a first organic insulating layer 123, a second organic insulating layer 124, a third organic insulating layer 125, and a fourth organic layer 121.

The first wirings WL1 may be arranged on the fourth organic layer 121, the second wiring WL2 may be arranged on the first organic insulating layer 123, and the third wirings WL3 may be arranged on the second organic insulating layer 124. Each of the first wirings WL1, the second wiring WL2, and the third wirings WL3 may be, as described herein, a signal line (e.g.. a gate line, a data line, or the like) configured to provide an electrical signal to a transistor included in the pixel circuit PC of the first island portion 11, or may be a voltage line (e.g., a power voltage line, an initialization voltage line, or the like) configured to provide a voltage to a transistor included in the pixel circuit PC of the first island portion 11.

The wirings WL may be arranged in a wiring area WA. The width of the wiring area WA may be less than the width of the bridge area 100b. For example, an edge of the wiring area WA may be separated inward from an edge of the bridge area 100b. FIG. 11A illustrates that two edges of the wiring area WA are respectively inwardly spaced apart from two edges of the bridge area 100b by a first distance d1.

In FIG. 11A, the upper surface 11us of the first island portion 11 and the upper surface 12us of the first bridge portion 12 may each be an upper surface of the third organic insulating layer 125. The side surface 11ss of the first island portion 11 may be a surface exposed by the opening CS, and a side surface of the island area 100a and a side surface of the first organic insulating stack OILa may form the side surface 11ss of the first island portion 11. The side surface 12ss of the first bridge portion 12 may be a surface exposed by the opening CS, and a side surface of the bridge area 100b and a side surface of the second organic insulating stack OILb may form the side surface 12ss of the first bridge portion 12.

The first protective layer 15 may be arranged such that the first protective layer 15 covers the upper surface 11us and the side surface 11ss of the first island portion 11 and the upper surface 12us and the side surface 12ss of the first bridge portion 12. The first protective layer 15 may be deposited on the upper surface 11us and the side surface 11ss of the first island portion 11 and the upper surface 12us and the side surface 12ss of the first bridge portion 12 by using conformal coating based on chemical vapor deposition. The first protective layer 15 may have openings respectively overlapping the first electrode pad 241 and the second electrode pad 242.

FIG. 11B illustrates the round portion RP (see FIG. 9A) of the first bridge portion 12. As described with reference to FIG. 9A, the first bridge portion 12 may include two round portions RP and a connection portion CP connecting the two round portions RP to each other. Each of the round portions RP may have an inner edge IE and an outer edge OE. The second protective layer 17 may extend along the inner edge IE of the first bridge portion 12. The second protective layer 17 may be arranged such that the second protective layer 17 covers the side surface 12ss of the first bridge portion 12. The second protective layer 17 may be arranged between the first protective layer 15 and the inner edge IE of the first bridge portion 12, and the first protective layer 15 may extend along and cover a side surface of the second protective layer 17, an upper surface of the second protective layer 17, the upper surface 12us of the first bridge portion 12, and an outer side surface of the first bridge portion 12.

In an embodiment, a material constituting the second protective layer 17 may be different from a material constituting the first protective layer 15. The modulus of the second protective layer 17 may be higher than the modulus of the first protective layer 15. By arranging the second protective layer 17 having a relatively high modulus between the inner edge IE of the first bridge portion 12 and the first protective layer 15, stress that is accumulated when the display panel 10 is stretched may be dispersed. Accordingly, by further reducing the second′ distance d2′ between the wiring area WA and the inner edge IE of the first bridge portion 12, the width of the wiring area WA in which the wirings WL are arranged may be sufficiently secured.

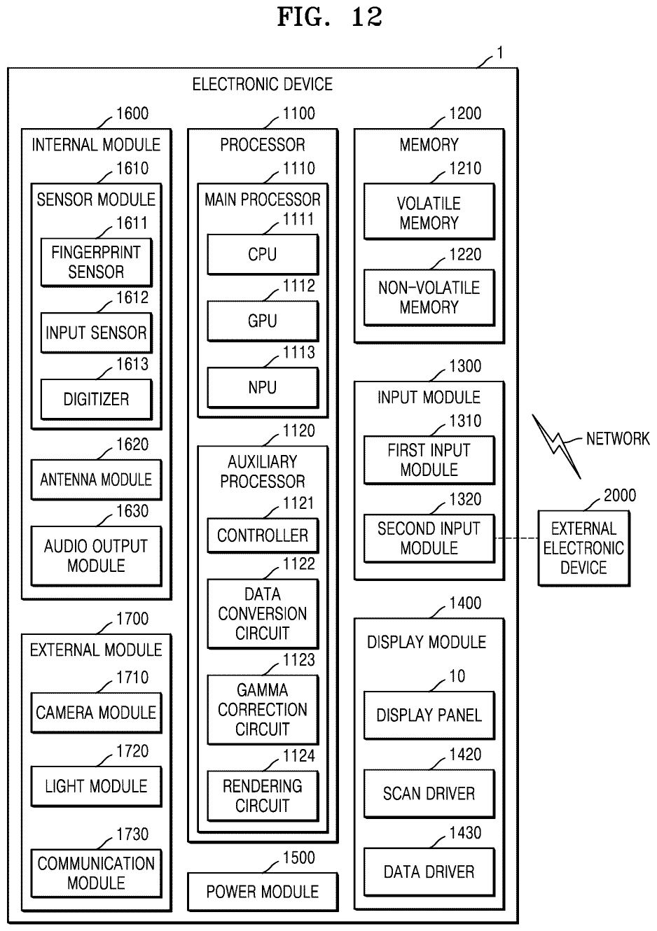

FIG. 12 is a block diagram of an electronic device including a display panel, according to an embodiment.

Referring to FIG. 12, an electronic device 1 may include a processor 1100, a memory 1200, an input module 1300, a display module 1400, a power module 1500, an internal module 1600, and an external module 1700. In an embodiment, at least one of the described components may be omitted from the electronic device 1, or one or more other components may be added to the electronic device 1. In an embodiment, some of the described components (e.g., the internal module 1600) may be integrated into another component (e.g., the display module 1400).

The processor 1100 may execute software to control at least one other component (e.g., a hardware or software component) of the electronic device 1 which is connected to the processor 1100, and may perform various data processing or computation. In an embodiment, as at least part of the data processing or computation, the processor 1100 may store a command or data received from another component (e.g., the input module 1300, a sensor module 1610, or a communication module 1730) in a volatile memory 1210, may process the command or data stored in the volatile memory 1210, and may store resulting data in a non-volatile memory 1220.

The processor 1100 may include a main processor 1110 and an auxiliary processor 1120. The main processor 1110 may include at least one of a central processing unit (CPU) 1111 and an application processor (AP). The main processor 1110 may further include at least one of a graphic processing unit (GPU) 1112, a communication processor (CP), and an image signal processor (ISP). The main processor 1110 may further include a neural processing unit (NPU) 1113. The NPU 1113 may be a processor specialized in processing an artificial intelligence model, and the artificial intelligence model may be generated through machine learning. The artificial intelligence model may include a plurality of artificial neural network layers. An artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more thereof, but is not limited to the described examples. The artificial intelligence model may additionally or alternatively include a software structure, in addition to a hardware structure. At least two of the processing units and processors described herein may be implemented as a single integrated component (e.g., a single chip), or may each be implemented as an independent component (e.g., a plurality of chips).

The auxiliary processor 1120 may include a controller 1121. The controller 1121 may include an interface conversion circuit and a timing control circuit. The controller 1121 may receive an image signal from the main processor 1110, and may convert a data format of the image signal to meet interface specifications with the display module 1400, and may output image data. The controller 1121 may output various control signals supportive of driving the display module 1400.

The auxiliary processor 1120 may further include data processing circuits, such as, for example, a data conversion circuit 1122, a gamma correction circuit 1123, and a rendering circuit 1124. The data conversion circuit 1122 may receive image data from the controller 1121, and may compensate for the image data such that an image is displayed with a desired luminance according to characteristics of the electronic device 1 or a user's settings, or may convert the image data to reduce power consumption or compensate for an afterimage. The gamma correction circuit 1123 may convert image data or a gamma reference voltage such that an image displayed on the electronic device 1 has desired gamma characteristics. The rendering circuit 1124 may receive image data from the controller 1121, and may render the image data by considering a pixel arrangement of the display panel 10 applied to the electronic device 1. At least one of the data conversion circuit 1122, the gamma correction circuit 1123, and the rendering circuit 1124 may be integrated into another component (e.g., the main processor 1110 or the controller 1121). In an embodiment, the auxiliary processor 1120 may be integrated into a data driver 1430.

The memory 1200 may store various data used by at least one component (e.g., the processor 1100 or the sensor module 1610) of the electronic device 1 and input data or output data for a command related thereto. The memory 1200 may include at least one of the volatile memory 1210 and the non-volatile memory 1220.

The input module 1300 may receive a command or data to be used by a component of the electronic device 1 (e.g., the processor 1100, the sensor module 1610, or an audio output module 1630) from an external source of the electronic device 1 (e.g., a user or an external electronic device 2000).

The input module 1300 may include a first input module 1310 to which a command or data is input from the user, and a second input module 1320 to which a command or data is input from the external electronic device 2000.

The first input module 1310 may include a microphone, a mouse, a keyboard, or a pen (e.g., a passive pen or an active pen). The first input module 1310 may include a mechanical input unit or a touch input unit, such as, for example, a button, a dome switch, a jog wheel, or a jog switch, located on a rear surface or a side surface of the electronic device 1. The touch input unit may include a touch screen layer of the display panel 10.

The second input module 1320 may be connected by wire or wirelessly to various types of external electronic devices 2000 connected to the electronic device 1. In an embodiment, the second input module 1320 may include a high definition multimedia interface (HDMI), a universal serial bus (USB) interface, a secure digital (SD) card interface, or an audio interface. The second input module 1320 may include a connector capable of physically connecting the electronic device 1 to the external electronic device 2000, for example, an HDMI connector, a USB connector, an SD card connector, or an audio connector (e.g., a headphone connector). In response to the external electronic device 2000 being connected to the second input module 1320, the electronic device 1 may perform appropriate control related to the external electronic device 2000 connected to the second input module 1320.

The display module 1400 may visually provide information to the user. The display module 1400 may include the display panel 10, a scan driver 1420, and the data driver 1430.

The display panel 10 may display (output) information processed by the electronic device 1. The display panel 10 may display execution screen information of an application running on the electronic device 1, or user interface (UI) and graphic user interface (GUI) information according to the execution screen information.

The scan driver 1420 may be mounted on the display panel 10 as a driving chip. Alternatively, the scan driver 1420 may be formed directly on the display panel 10. For example, the scan driver 1420 may include an amorphous silicon thin film transistor (TFT) gate driver circuit (ASG), a low-temperature polycrystalline silicon (LTPS) TFT gate driver circuit, or an oxide semiconductor TFT gate driver circuit (OSG), which is embedded in the display panel 10. The scan driver 1420 may receive a control signal from the controller 1121, and may output scan signals to the display panel 10 in response to the control signal.

The display panel 10 may further include an emission control driver. The emission control driver may output an emission control signal to the display panel 10 in response to a control signal received from the controller 1121. The emission control driver may be formed separately from the scan driver 1420, or may be integrated into the scan driver 1420.

The data driver 1430 may receive a control signal from the controller 1121, may convert image data into a data voltage in the form of an analog voltage in response to the control signal, and may output the data voltage to the display panel 10.

The data driver 1430 may be integrated with some components of the auxiliary processor 1120. For example, the data driver 1430 may be provided as a timing controller embedded driver integrated circuit (IC) including the controller 1121.

The power module 1500 may supply power to components of the electronic device 1. The power module 1500 may include a battery for charging a power voltage. In some aspects, the power module 1500 may have a connection port, and the connection port may be included in the second input module 1320 to which an external charger that supplies power for charging the battery is connected. Alternatively, the power module 1500 may include a wireless power transmission/reception member to charge the battery wirelessly. The wireless power transmission/reception member may include a plurality of coil-shaped antenna radiators. The power module 1500 may include a power management integrated circuit (PMIC). The PMIC may supply optimized power to each component of the electronic device 1.

The electronic device 1 may further include the internal module 1600 and the external module 1700. The internal module 1600 may include the sensor module 1610, an antenna module 1620, and the audio output module 1630. The external module 1700 may include a camera module 1710, a light module 1720, and/or the communication module 1730.

The sensor module 1610 may include touch electrodes of the touch screen layer of the display panel 10 and a touch sensor driver. The sensor module 1610 may sense an input by the user's body or an input by a pen, and may generate an electric signal or a data value corresponding to the input. The sensor module 1610 may include at least one of a fingerprint sensor 1611, an input sensor 1612, and a digitizer 1613.

The fingerprint sensor 1611 may generate a data value corresponding to a fingerprint of the user. The fingerprint sensor 1611 may include an optical fingerprint sensor or a capacitive fingerprint sensor.

The input sensor 1612 may generate a data value corresponding to coordinate information of an input by the user's body or an input by a pen. The input sensor 1612 may generate a capacitance change amount due to the input as a data value. The input sensor 1612 may sense an input by a passive pen, or may transmit and receive data with an active pen.

The input sensor 1612 may measure a biometric signal, such as, for example, blood pressure, moisture, or body fat. In an example in which the user touches a sensor layer or a sensing panel with a body part and does not move for a certain period of time, based on a change in an electric field due to the body part, the input sensor 1612 may sense a biometric signal and output information desired by the user to the display module 1400.

The digitizer 1613 may generate a data value corresponding to coordinate information of an input by a pen. The digitizer 1613 may generate an electromagnetic change amount due to the input as a data value. The digitizer 1613 may sense an input by a passive pen, or may transmit and receive data with an active pen.

In an embodiment, at least one of the fingerprint sensor 1611, the input sensor 1612, and the digitizer 1613 may be embedded in the display panel 10. For example, at least one of the fingerprint sensor 1611, the input sensor 1612, and the digitizer 1613 may be formed through a process that is continuous with a process of forming pixel circuits and light-emitting diodes of the display panel 10. As a result, the display panel 10 may function as one of the input modules 1300 that provide an input interface between the electronic device 1 and the user, and may also function as the display module 1400 that provides an output interface between the electronic device 1 and the user.

In an embodiment, at least two of the fingerprint sensor 1611, the input sensor 1612, and the digitizer 1613 may be formed to be integrated into one sensing panel through the same process. The sensing panel may be arranged between the display panel 10 and a window arranged above the display panel 10, but the disclosure is not limited thereto.

The antenna module 1620 may include one or more antennas for transmitting or receiving a signal or power to or from the outside. In an embodiment, the communication module 1730 may transmit a signal to an external electronic device, or may receive a signal from an external electronic device through an antenna suitable for a communication method. An antenna pattern of the antenna module 1620 may be integrated into one component (e.g., the display panel 10) of the display module 1400 or the input sensor 1612.

The audio output module 1630 may be a device for outputting an audio signal to the outside of the electronic device 1, and may output audio data received from the communication module 1730 or stored in the memory 1200, in a call signal reception mode, a call mode, a recording mode, a voice recognition mode, a broadcast reception mode, or the like. The audio output module 1630 may output an audio signal related to a function performed in the electronic device 1 (e.g., a call signal reception sound, a message reception sound, or the like). The audio output module 1630 may include a receiver and a speaker. At least one of the receiver and the speaker may be an audio generation device that is attached to a lower portion of the display panel 10 to vibrate the display panel 10 and output sound. The audio generation device may be a piezoelectric element or a piezoelectric actuator that contracts and expands in response to an electric signal, or may be an exciter that generates magnetic force by using a voice coil and vibrates the display panel 10.

The camera module 1710 may capture a still image and a moving image. In an embodiment, the camera module 1710 may include one or more lenses, image sensors, or image signal processors. The camera module 1710 may further include an infrared camera capable of measuring the presence or absence of the user, the user's location, the user's gaze, or the like.

The light module 1720 may output a signal to notify the occurrence of an event by using light from a light source, or may provide light for image acquisition. Here, examples of the occurrence of an event may include receiving a message, receiving a call signal, a missed call, an alarm, a schedule notification, receiving an email, a notification on battery charging capacity information, or the like. The light module 1720 may include a light-emitting diode or a xenon lamp. The light module 1720 may emit light of a single color or multiple colors to a front surface or a rear surface of the electronic device 1. The light module 1720 may operate in conjunction with the camera module 1710, or may operate independently.

The communication module 1730 may support establishing a wired or wireless communication channel between the electronic device 1 and the external electronic device 2000 and performing communication through the established communication channel. The communication module 1730 may include one or both of a wireless communication module, such as, for example, a cellular communication module, a short-range wireless communication module, or a global navigation satellite system (GNSS) communication module, and a wired communication module, such as, for example, a local area network (LAN) communication module or a power line communication module. The communication module 1730 may transmit and receive a wireless signal on the Internet by using at least one of Wireless LAN (WLAN), Wireless-Fidelity (Wi-Fi), Wi-Fi Direct, and Digital Living Network Alliance (DLNA) technologies. In some aspects, the communication module 1730 may support short-range communication by using at least one of Bluetooth™, Radio Frequency Identification (RFID), Infrared Data Association (IrDA), Ultra Wideband (UWB), ZigBee, Near Field Communication (NFC), Wi-Fi, Wi-Fi Direct, and Wireless USB technologies. The various types of communication modules 1730 described herein may be implemented as one chip or as separate chips.

The electronic device 1 may be freely deformed three-dimensionally, thereby providing a three-dimensionally deformable image surface. In another embodiment, the electronic device 1 may include an image provision area having a fixed shape, wherein, in a process of manufacturing the electronic device 1, the display panel 10 may be arranged in the image provision area of the electronic device 1, and the display panel 10 may be fixed to the electronic device 1 in a three-dimensionally deformed state.

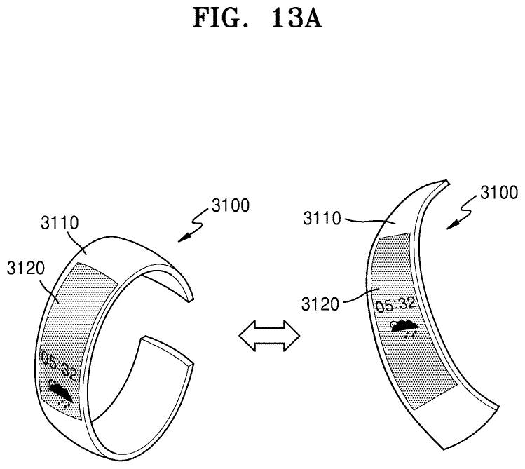

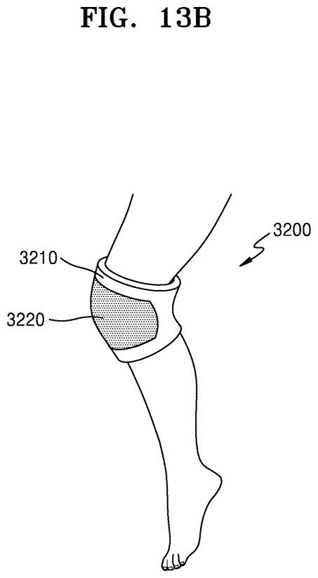

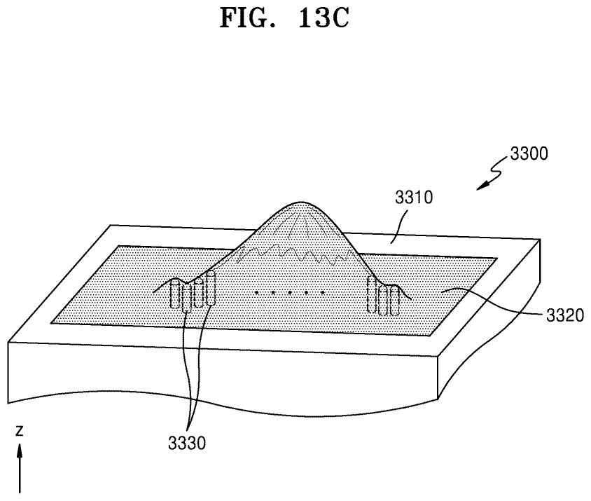

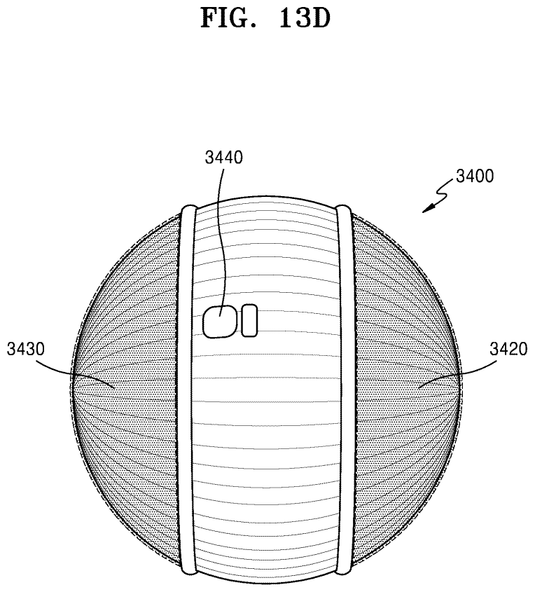

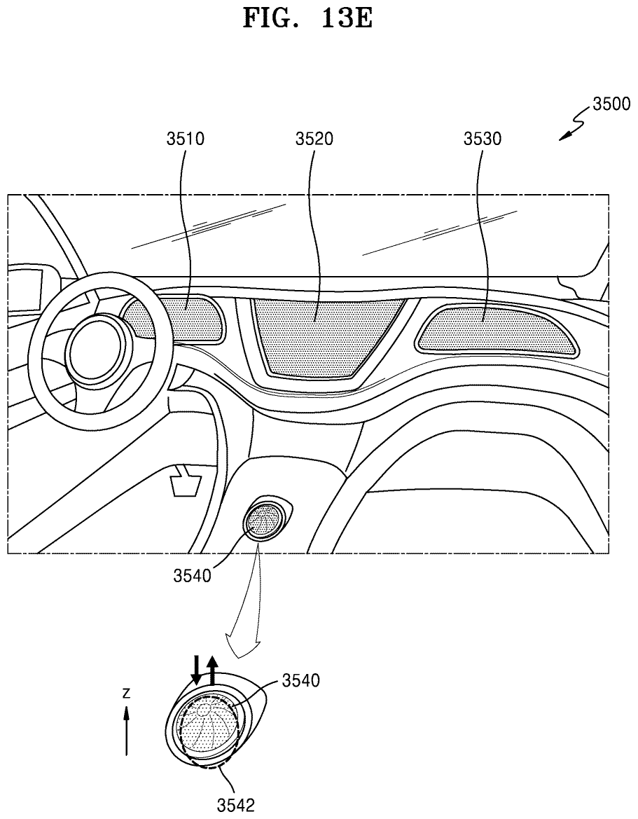

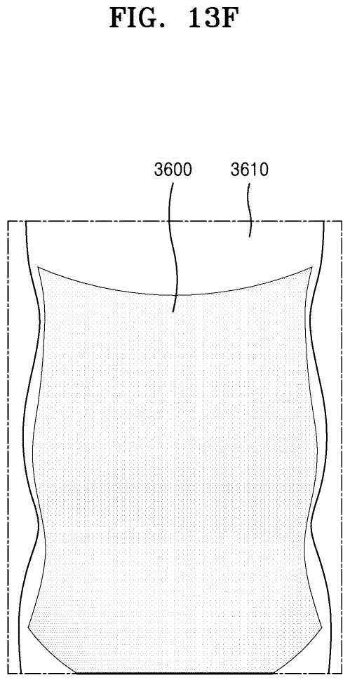

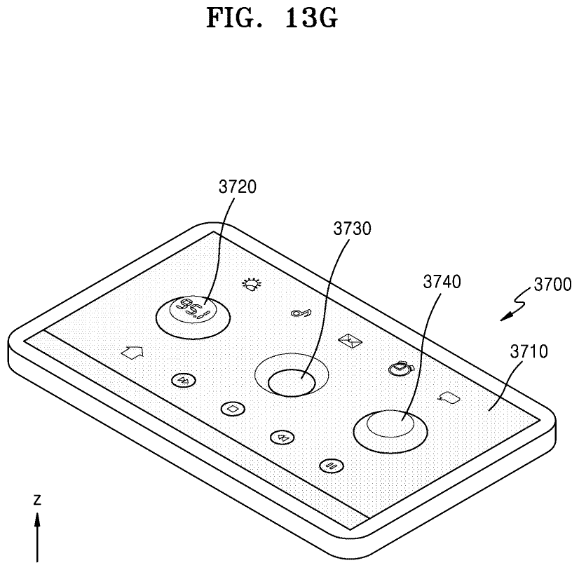

FIGS. 13A to 13G are each a schematic perspective view of an embodiment of an electronic device including a display panel, according to an embodiment.

Referring to FIG. 13A, a display panel according to an embodiment may be used in a wearable electronic device 3100 that may be worn on a part of a user's body. The wearable electronic device 3100 may include a body portion 3110 and a display 3120 provided on the body portion 3110. A display panel according to an embodiment may be used as the display 3120 of the wearable electronic device 3100. As illustrated in FIG. 13A, the wearable electronic device 3100 may be deformable. In an embodiment, the wearable electronic device 3100 may be used as a smart watch or a smartphone according to the user's choice.

FIG. 13B illustrates a medical electronic device 3200. In an embodiment, the medical electronic device 3200 may include a body portion 3210 and an emission portion 3220. A display panel according to an embodiment may be used as the emission portion 3220 of the medical electronic device 3200. The emission portion 3220 may emit light of a certain wavelength band (e.g., infrared light, visible light, or the like) to a patient's body. In an embodiment, the body portion 3210 may include a stretchable fiber material, and may have a structure that may be worn on the body of a user of the emission portion 3220.

FIG. 13C illustrates an educational electronic device 3300. In an embodiment, the educational electronic device 3300 may include a display 3320 provided within a frame 3310. The display 3320 may use a display panel according to an embodiment. The display 3320 may provide an image of a sea with waves, a mountain covered in snow, or a volcano with flowing lava, and in this case, the display 3320 may be stretched in a height direction (e.g., the z-direction) to reflect the height of the waves, the mountain, or the volcano. In some embodiments, the height of a portion of the display 3320 may sequentially vary in a direction in which the lava flows, thereby displaying movement of the lava in three dimensions. The educational electronic device 3300 may include a plurality of pins (or stroke portions) 3330 arranged on a rear surface of the display 3320 such that the display 3320 is stretched in the height direction. As the pins 3330 move in the third direction (e.g., the z-direction or the −z-direction), an image expressed on the display 3320 may be implemented to have a three-dimensional height. While FIG. 13C illustrates the educational electronic device 3300, the use of the illustrated electronic device 3300 is not limited as long as the electronic device 3300 provides certain image information.

The electronic devices illustrated in FIGS. 13A to 13C may each have a variable shape, but the disclosure is not limited thereto. As described in the following embodiments, a display panel according to an embodiment may be used in an electronic device in which a portion capable of expressing an image (e.g., a screen) is fixed.

FIG. 13D illustrates a robot 3400 as an electronic device according to an embodiment. The robot 3400 may recognize movement or an object by using a camera 3440 and may display a certain image to a user through displays 3420 and 3430. In some embodiments, because display panels according to embodiments may be stretched in various directions, as described herein, the display panels may be assembled into a body frame having a hemispherical shape. Thus, the robot 3400 may include the displays 3420 and 3430 each having a hemispherical shape.

FIG. 13E illustrates a vehicle display device 3500 as an electronic device according to an embodiment. The vehicle display device 3500 may include a cluster 3510, a center information display (CID) 3520, and/or a passenger display 3530. Because a display panel according to an embodiment may be stretched in various directions, the display panel may be used for the cluster 3510, the CID 3520, and/or the passenger display 3530, regardless of the shape of an internal frame of the vehicle.

FIG. 13E illustrates that the cluster 3510, the CID 3520, and/or the passenger display 3530 are separate from each other, but the disclosure is not limited thereto. In another embodiment, two or more selected from the cluster 3510, the CID 3520, and/or the passenger display 3530 may be connected to each other in a single body.

In some embodiments, the vehicle display device 3500 may include a button 3540 capable of expressing a certain image. Referring to the enlarged view of FIG. 13E, the button 3540 having a hemispherical shape may include an object 3542 for providing a feeling of use of the button 3540 while moving in the z-direction or the −z-direction, and an electronic device arranged on the object 3542. In some embodiments, when the object 3542 has a three-dimensionally round surface, the electronic device may also have a three-dimensionally round surface.

FIG. 13F illustrates an electronic device 3600 for advertising or exhibition as an electronic device according to an embodiment. In some embodiments, the electronic device 3600 for advertising or exhibition may be installed on a structure 3610 that is fixed, such as, for example, a wall or a pillar. In an example in which the structure 3610 includes an uneven surface as illustrated in FIG. 13F, the electronic device 3600 for advertising or exhibition may be arranged along the uneven surface of the structure 3610. In some embodiments, the electronic device 3600 for advertising or exhibition may be installed on the structure 3610 by using a heat-shrink film, or the like.

FIG. 13G illustrates a controller 3700 as an electronic device according to an embodiment. The controller 3700 may include an image-type button. For example, the controller 3700 may include a first button area 3720, a second button area 3730, and a third button area 3740 in which portions of a display 3710 protrude in the z-direction or protrude in the −z-direction (or are recessed in the z-direction). In some embodiments, the first button area 3720 and the third button area 3740 may protrude in the z-direction, and the second button area 3730 may protrude in the −z-direction (or be recessed in the z-direction).

According to one or more embodiments described herein, a high-resolution display panel having high elasticity and an electronic device including the display panel may be implemented. However, the scope of the disclosure is not limited thereto.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate comprising a plurality of island portions and a plurality of bridge portions connecting adjacent island portions among the plurality of island portions to each other;
a display layer arranged on the substrate and comprising a plurality of pixels and a plurality of wirings, wherein the plurality of pixels are arranged in the plurality of island portions, and the plurality of wirings are arranged in the plurality of bridge portions; and
a first protective layer covering a side surface of the substrate and a side surface of the display layer,
wherein the first protective layer is arranged such that the first protective layer is spaced apart from the plurality of pixels in a plan view.

2. The display panel of claim 1, wherein the substrate further comprises:
at least one base layer comprising an organic insulating material; and
at least one barrier layer arranged on the at least one base layer and comprising an inorganic insulating material,
wherein the at least one barrier layer is spaced apart from the plurality of bridge portions in the plan view.

3. The display panel of claim 1, wherein the display layer further comprises:
a pixel circuit arranged in each of the plurality of island portions;
a first organic insulating layer arranged on the pixel circuit;
a first electrode pad and a second electrode pad that are arranged on the first organic insulating layer; and
a light-emitting diode arranged on the first electrode pad and the second electrode pad.

4. The display panel of claim 3, wherein:
the display layer further comprises at least one inorganic insulating layer, and
the at least one inorganic insulating layer is spaced apart from the plurality of bridge portions in the plan view.

5. The display panel of claim 3, further comprising an encapsulation layer arranged on the light-emitting diode,
wherein the first protective layer covers a side surface of the encapsulation layer.

6. The display panel of claim 5, wherein the first protective layer exposes an upper surface of the encapsulation layer.

7. The display panel of claim 1, wherein each of the plurality of bridge portions has a serpentine shape.

8. The display panel of claim 7, wherein each of the plurality of bridge portions comprises:
two round portions each having an inner edge and an outer edge; and
a connection portion connecting the two round portions to each other.

9. The display panel of claim 8, wherein:
each of the plurality of bridge portions has a wiring area in which the plurality of wirings are arranged, and
the wiring area is spaced apart from the outer edge by a first distance and is spaced apart from the inner edge by a second distance that is greater than the first distance.

10. The display panel of claim 8, further comprising a second protective layer arranged between the inner edges and the first protective layer.

11. The display panel of claim 10, wherein a modulus of the second protective layer is higher than a modulus of the first protective layer.

12. The display panel of claim 7, wherein each of the plurality of bridge portions comprises:
two corner portions each having a first portion and a second portion that are connected to each other, wherein the first portion extends in a first direction, and the second portion extends in a second direction crossing the first direction; and
a connection portion connecting the two corner portions to each other.

13. The display panel of claim 12, wherein:
each of the two corner portions has an inner edge and an outer edge, and
the display panel further comprises a second protective layer arranged between the inner edges and the first protective layer.

14. The display panel of claim 13, wherein a modulus of the second protective layer is higher than a modulus of the first protective layer.

15. The display panel of claim 1, wherein the first protective layer comprises parylene, silicon oxide, or silicon nitride.

16. A display panel comprising:
a substrate comprising a plurality of island portions and a plurality of bridge portions connecting adjacent island portions among the plurality of island portions to each other;
a pixel circuit arranged in each of the plurality of island portions;
a first organic insulating layer arranged on the pixel circuit;
a first electrode pad and a second electrode pad that are arranged on the first organic insulating layer;
a light-emitting diode arranged on the first electrode pad and the second electrode pad;
a first protective layer extending from an upper surface of the first organic insulating layer to a side surface of the substrate and having openings respectively corresponding to the first electrode pad and the second electrode pad; and
a second protective layer arranged between the first protective layer and side surfaces of the plurality of bridge portions.

17. The display panel of claim 16, wherein the substrate further comprises:
at least one base layer comprising an organic insulating material; and
at least one barrier layer arranged on the at least one base layer and comprising an inorganic insulating material,
wherein the at least one barrier layer is spaced apart from the plurality of bridge portions in a plan view.

18. The display panel of claim 16, wherein each of the plurality of bridge portions comprises:
two round portions each having an inner edge and an outer edge; and
a connection portion connecting the two round portions to each other,
wherein the second protective layer is arranged along the inner edges.

19. The display panel of claim 18, wherein a modulus of the second protective layer is higher than a modulus of the first protective layer.

20. An electronic device comprising a display panel capable of being stretched, wherein the display panel comprises:
a substrate comprising a plurality of island portions and a plurality of bridge portions connecting adjacent island portions among the plurality of island portions to each other;
a display layer arranged on the substrate and comprising a plurality of pixels and a plurality of wirings, wherein the plurality of pixels are arranged in the plurality of island portions, and the plurality of wirings are arranged in the plurality of bridge portions; and
a first protective layer covering a side surface of the substrate and a side surface of the display layer,
wherein the first protective layer is arranged such that the first protective layer is spaced apart from the plurality of pixels in a plan view.
